(19) United States
(12) Patent Application Publication
(10) Pub. No.: US 2025/0273636 A1
(43) Pub. Date: Aug. 28, 2025

(54) LIGHT-EMITTING COMPONENT AND DISPLAY DEVICE INCLUDING THE SAME

(71) Applicant: LG Display Co., Ltd., Seoul (KR)

(72) Inventors: DongSeok LEE, Bucheon-si (KR); Hyuk-Chan GEE, Gumi-si (KR); HyeongSeok KIM, Paju-si (KR)

(21) Appl. No.: 18/932,069

(22) Filed: Oct. 30, 2024

(30) Foreign Application Priority Data
Feb. 28, 2024 (KR) 10-2024-0028738

(51) Int. Cl. H01L 25/075; H01L 25/16; H01L 33/38; H01L 33/62

(52) U.S. Cl. CPC H01L 25/0756; H01L 25/167; H10H 20/831; H10H 20/857

(57) ABSTRACT

Disclosed are a light-emitting component and a display device including the same. The light-emitting component includes a first light-emitting element, a second light-emitting element, and a bonding layer between the first and second light-emitting elements. The first and second light-emitting elements each have a first electrode, a first semiconductor layer, an active layer, a second semiconductor layer, and a second electrode are sequentially stacked, and in which the order in which the first electrode, the first semiconductor layer, the active layer, the second semiconductor layer, and the second electrode of the first light-emitting element are stacked and the order in which the first electrode, the first semiconductor layer, the active layer, the second semiconductor layer, and the second electrode of the second light-emitting element are stacked are opposite to each other. Therefore, the light-emitting elements may be autonomously assembled in two directions.

### CROSS-REFERENCE TO RELATED APPLICATIONS

This application claims the priority of Korean Patent Application No. 10-2024-0028738 filed on Feb. 28, 2024, in the Korean Intellectual Property Office, the disclosure of which is incorporated herein by reference.

### TECHNICAL FIELD

The present specification relates to a light-emitting component and a display device including the same, and more particularly, to a light-emitting component, which is capable of being assembled in two directions, and a display device including the same.

### DESCRIPTION OF THE RELATED ART

As display devices used for a monitor of a computer, a TV set, a mobile phone, and the like, there are an organic light-emitting display (OLED) configured to autonomously emit, and a liquid crystal display (LCD) that requires a separate light source.

The range of application of the display devices is diversified from the monitor of the computer and the TV set to personal mobile devices, and studies are being conducted on the display devices having wide display areas and having reduced volumes and weights.

In addition, recently, a display device including a light-emitting diode (LED) has attracted attention as a next-generation display device. Because the LED is made of an inorganic material instead of an organic material, the LED is more reliable and has a longer lifespan than a liquid crystal display device or an organic light-emitting display device. In addition, the LED may be quickly turned on or off, have excellent luminous efficiency, high impact resistance, and great stability, and display high-brightness images.

### BRIEF SUMMARY

Various embodiments of the present specification provide a light-emitting component, which is capable of being assembled in two directions, and a display device including the same.

Various embodiments of the present specification provide a light-emitting component, which is capable of emitting light regardless of an assembling direction, and a display device including the same.

Still another object to be achieved by the present specification is to provide a light-emitting component, which is capable of facilitating electrical connection, and a display device including the same.

Various embodiments of the present specification provide a light-emitting component, which has improved luminous efficiency regardless of an assembling direction, and a display device including the same.

Various embodiments of the present specification provide a light-emitting component, which has high luminance, and a display device including the same.

Technical benefits of the present disclosure are not limited to the above-mentioned benefits, and other benefits, which are not mentioned above, can be clearly understood by those skilled in the art from the following descriptions.

A light-emitting component according to an embodiment of the present disclosure may include a first light-emitting element, a second light-emitting element disposed on the first light-emitting element and a bonding layer disposed between the first light-emitting element and the second light-emitting element, in which the first light-emitting element and the second light-emitting element each have a structure in which a first electrode, a first semiconductor layer, an active layer, a second semiconductor layer, and a second electrode are sequentially stacked, and in which the order in which the first electrode, the first semiconductor layer, the active layer, the second semiconductor layer, and the second electrode of the first light-emitting element are stacked and the order in which the first electrode, the first semiconductor layer, the active layer, the second semiconductor layer, and the second electrode of the second light-emitting element are stacked are opposite to each other. Therefore, the light-emitting elements may be autonomously assembled in two directions.

A display device according to an embodiment of the present disclosure may comprise: a substrate comprising a plurality of subpixels; a plurality of transistors disposed on the substrate; a power line disposed on the substrate; and a plurality of light-emitting components disposed on the plurality of transistors in the plurality of subpixels, wherein the plurality of light-emitting components each comprises: a first light-emitting element; a second light-emitting element disposed on the first light-emitting element; and a bonding layer disposed between the first light-emitting element and the second light-emitting element, wherein the first light-emitting element and the second light-emitting element each have a structure in which a first electrode, a first semiconductor layer, an active layer, a second semiconductor layer, and a second electrode are sequentially stacked, and wherein the order in which the first electrode, the first semiconductor layer, the active layer, the second semiconductor layer, and the second electrode of the first light-emitting element are stacked and the order in which the first electrode, the first semiconductor layer, the active layer, the second semiconductor layer, and the second electrode of the second light-emitting element are stacked are opposite to each other.

Other detailed matters of the exemplary embodiments are included in the detailed description and the drawings.

According to the present specification, two light-emitting elements may be disposed in one subpixel and simultaneously turned on, thereby implementing high luminance.

According to the present specification, two light-emitting elements disposed in one subpixel are disposed symmetrically, such that the two light-emitting elements may be assembled in the two directions.

According to the present specification, it is possible to facilitate electrical connection of the light-emitting element.

According to the present specification, the lifespan of the display device may be improved by minimizing or reducing the likelihood of a potential defect, such as an image quality defect of the display device, such that the display device may operate with low power consumption, and the production energy may be reduced.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a cross-sectional view of a light-emitting component according to an embodiment of the present specification;

FIG. 2 is a cross-sectional view of a light-emitting component according to another embodiment of the present specification;

FIG. 3 is a cross-sectional view of a light-emitting component according to still another embodiment of the present specification;

FIG. 4 is a cross-sectional view of a light-emitting component according to yet another embodiment of the present specification;

FIG. 5 is a schematic configuration view of the display device according to the embodiment of the present specification;

FIG. 6 is a cross-sectional view of one subpixel of the display device according to the embodiment of the present specification;

FIG. 7 is a cross-sectional view of a display device according to another embodiment of the present specification;

FIG. 8 is a cross-sectional view of a display device according to still another embodiment of the present specification;

FIG. 9 is a cross-sectional view of a display device according to yet another embodiment of the present specification;

FIG. 10 is a cross-sectional view of a display device according to still yet another embodiment of the present specification;

FIG. 11 is a cross-sectional view of a display device according to a further embodiment of the present specification;

FIG. 12 is a cross-sectional view of a display device according to another further embodiment of the present specification;

FIG. 13 is a cross-sectional view of a display device according to still another further embodiment of the present specification; and

FIG. 14 is a cross-sectional view of a display device according to yet another further embodiment of the present specification.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, numbers, and the like illustrated in the accompanying drawings for describing the exemplary embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, the element or layer may be disposed on another element or layer directly, or the other layer or the other element may be interposed.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

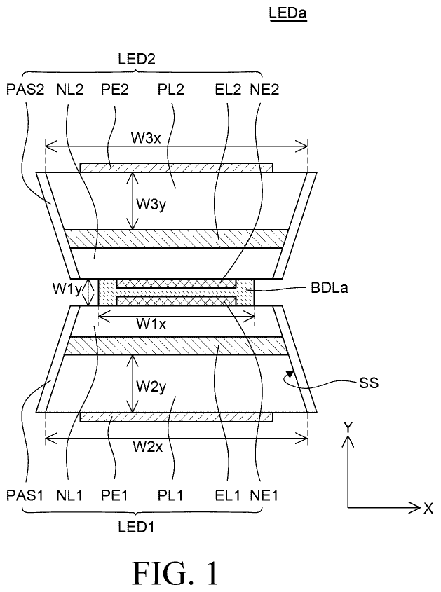

FIG. 1 is a cross-sectional view of a light-emitting component according to an embodiment of the present specification.

With reference to FIG. 1, a light-emitting component LEDa according to an embodiment of the present specification may include a first light-emitting element LED1, a bonding layer BDLa, and a second light-emitting element LED2.

The first light-emitting element LED1 may include a first electrode PE1, a first semiconductor layer PL1, an active layer EL1, a second semiconductor layer NL1, a second electrode NE1, and a passivation film PAS1.

The first electrode PE1 is a layer for injecting positive holes into the active layer EL1 through the first semiconductor layer PL1. The first electrode PE1 may be made of an electrically conductive material, e.g., a transparent conductive material such as indium tin oxide (ITO) or indium zinc oxide (IZO).

The first semiconductor layer PL1 may be disposed on the first electrode PE1. The first semiconductor layer PL1 is a layer for injecting positive holes into the active layer EL1. The first semiconductor layer PL1 may be formed by doping a gallium nitride (GaN) semiconductor layer, which is formed by growing a gallium nitride (GaN) layer, with p-type impurities such as magnesium (Mg), zinc (Zn), and beryllium (Be). However, the present specification is not limited thereto.

The active layer EL1 may be disposed on the first semiconductor layer PL1. The active layer EL1 may emit light by receiving positive holes and electrons from the first semiconductor layer PL1 and the second semiconductor layer NL1. The active layer EL1 may be configured as a single layer or a multi-quantum well (MQW) structure. For example, the active layer EL1 may be made of indium gallium nitride (InGaN), gallium nitride (GaN), or the like. However, the present specification is not limited thereto.

The second semiconductor layer NL1 may be disposed on the active layer EL1. The second semiconductor layer NL1 is a layer for supplying electrons to the active layer EL1. For example, the second semiconductor layer NL1 may be formed by doping a gallium nitride (GaN) semiconductor layer, which is formed by growing a gallium nitride (GaN) layer, with n-type impurities such as silicon (Si). However, the present specification is not limited thereto.

The passivation film PAS1 may be disposed on a side surface of the first semiconductor layer PL1, a side surface of the active layer EL1, and a side surface of the second semiconductor layer NL1. The passivation film PAS1 is a film for protecting the first semiconductor layer PL1, the active layer EL1, and the second semiconductor layer NL1. For example, the passivation film PAS1 may be made of light transmissive epoxy, aluminum oxide (Al₂O₃), silicon oxide (SiOx), or silicon nitride (SiNx). However, the present specification is not limited thereto.

The second electrode NE1 may be disposed on the second semiconductor layer NL1. The second electrode NE1 is a layer disposed to inject electrons into the active layer EL1 through the second semiconductor layer NL1. For example, the second electrode NE1 may include a magnetic element so that the second electrode NE1 may be moved by a magnetic field. For example, the second electrode NE1 may include a ferromagnetic element material such as iron (Fe), cobalt (Co), or nickel (Ni), such that the light-emitting component LEDa may be moved toward a magnet of an assembling substrate.

The bonding layer BDLa may be disposed on the first light-emitting element LED1. The bonding layer BDLa may be disposed between the first light-emitting element LED1 and the second light-emitting element LED2 and fix the first light-emitting element LED1 and the second light-emitting element LED2. Meanwhile, the bonding layer BDLa may be electrically connected to the first light-emitting element LED1 and the second light-emitting element LED2 so that the first light-emitting element LED1 and the second light-emitting element LED2 operate together. Specifically, the bonding layer BDLa may be disposed between the second electrode NE1 of the first light-emitting element LED1 and a second electrode NE2 of the second light-emitting element LED2 and electrically connect the second electrode NE1 of the first light-emitting element LED1 and the second electrode NE2 of the second light-emitting element LED2.

The bonding layer BDLa may be made of a metallic material to electrically connect the first light-emitting element LED1 and the second light-emitting element LED2. For example, the bonding layer BDLa may be made of a metallic material capable of bonding, by eutectic bonding, the second electrode NE1 of the first light-emitting element LED1 and the second electrode NE2 of the second light-emitting element LED2. However, the present specification is not limited thereto.

Meanwhile, a width of the bonding layer BDLa may be smaller than a width of the first semiconductor layer PL1 of the first light-emitting element LED1 and a width of a first semiconductor layer PL2 of the second light-emitting element LED2. For example, as shown in FIG. 1, a width W1x of the bonding layer BDLa in a first direction (e.g., X-axis direction) may be smaller than a width W2x of the first semiconductor layer PL1 of the first light-emitting element LED1 in the same direction (e.g., X-axis direction) and a width W3x of a first semiconductor layer PL2 of the second light-emitting element LED2 in the same direction (e.g., X-axis direction). Additionally, a width W1y of the bonding layer BDLa in a second direction (e.g., Y-axis direction) may be smaller than a width W2y of the first semiconductor layer PL1 of the first light-emitting element LED1 in the same direction (e.g., Y-axis direction) and a width W3y of a first semiconductor layer PL2 of the second light-emitting element LED2 in the same direction (e.g., Y-axis direction). However, the present specification is not limited thereto.

The second light-emitting element LED2 may be disposed on the bonding layer BDLa. The second light-emitting element LED2 and the first light-emitting element LED1 are shaped symmetrically with respect to the bonding layer BDLa so that the light-emitting component LEDa may be assembled in two directions. That is, like the first light-emitting element LED1, the second light-emitting element LED2 may include a first electrode PE2, the first semiconductor layer PL2, an active layer EL2, a second semiconductor layer NL2, the second electrode NE2, and a passivation film PAS2. However, the order in which the first electrode, the first semiconductor layer, the active layer, the second semiconductor layer, and the second electrode of the second light-emitting element LED2 are stacked may be opposite to the order in which the first electrode, the first semiconductor layer, the active layer, the second semiconductor layer, and the second electrode of the first light-emitting element LED1 are stacked.

The configuration has been described with reference to FIG. 1 in which the first semiconductor layers PL1 and PL2 are layers for injecting positive holes, the second semiconductor layers NL1 and NL2 are layers for injecting electrons, and the second semiconductor layers NL1 and NL2 are connected through the second electrodes NE1 and NE2 and the bonding layer BDLa while facing each other. However, the present specification is not limited thereto. On the contrary, the first semiconductor layers PL1 and PL2 may be layers for injecting electrons, the second semiconductor layers NL1 and NL2 may be layers for injecting positive holes, and the second semiconductor layers NL1 and NL2 may be connected through the second electrodes NE1 and NE2 and the bonding layer BDLa while facing each other.

Meanwhile, because the first light-emitting element LED1 and the second light-emitting element LED2 are disposed in the same subpixel in the display device as described below, the second light-emitting element LED2 may emit light with the same color as the first light-emitting element LED1.

The second electrode NE2 may be disposed on the bonding layer BDLa. The second electrode NE2 is a layer disposed to inject electrons into the active layer EL2 through the second semiconductor layer NL2. For example, the second electrode NE2 may include a magnetic element so that the second electrode NE2 may be moved by a magnetic field. For example, the second electrode NE1 may include a ferromagnetic element material such as iron (Fe), cobalt (Co), or nickel (Ni), such that the light-emitting component LEDa may be moved toward the magnet of the assembling substrate.

The second semiconductor layer NL2 may be disposed on the second electrode NE2. The second semiconductor layer NL2 is a layer for supplying electrons to the active layer EL2. For example, the second semiconductor layer NL2 may be formed by doping a gallium nitride (GaN) semiconductor layer, which is formed by growing a gallium nitride (GaN) layer, with n-type impurities such as silicon (Si). However, the present specification is not limited thereto.

The active layer EL2 may be disposed on the second semiconductor layer NL2. The active layer EL2 may emit light by receiving positive holes and electrons from the first semiconductor layer PL2 and the second semiconductor layer NL2. The active layer EL2 may be configured as a single layer or a multi-quantum well (MQW) structure. For example, the active layer EL2 may be made of indium gallium nitride (InGaN), gallium nitride (GaN), or the like. However, the present specification is not limited thereto.

The first semiconductor layer PL2 may be disposed on the active layer EL2. The first semiconductor layer PL2 is a layer for injecting positive holes into the active layer EL2. The first semiconductor layer PL2 may be formed by doping a gallium nitride (GaN) semiconductor layer, which is formed by growing a gallium nitride (GaN) layer, with p-type impurities such as magnesium (Mg), zinc (Zn), and beryllium (Be). However, the present specification is not limited thereto.

The passivation film PAS2 may be disposed on a side surface of the first semiconductor layer PL2, a side surface of the active layer EL2, and a side surface of the second semiconductor layer NL2. The passivation film PAS2 is a film for protecting the first semiconductor layer PL2, the active layer EL2, and the second semiconductor layer NL2. For example, the passivation film PAS2 may be made of light transmissive epoxy, aluminum oxide (Al₂O₃), silicon oxide (SiOx), or silicon nitride (SiNx). However, the present specification is not limited thereto.

The first electrode PE2 on the first semiconductor layer PL2 is a layer for injecting positive holes into the active layer EL2 through the first semiconductor layer PL2. The first electrode PE2 may be made of an electrically conductive material, e.g., a transparent conductive material such as indium tin oxide (ITO) or indium zinc oxide (IZO).

An autonomous assembling method may be used as one of the methods of manufacturing the display device. The display device may be manufactured by autonomously assembling a light-emitting component to a separate assembling substrate and then transferring the autonomously assembled light-emitting component from the assembling substrate to a display panel substrate by using an interposer.

Specifically, the light-emitting components may be dispersed in a bath including a fluid, and then the assembling substrate including grooves for assembling the light-emitting components may be disposed on the bath. In this case, a magnet may be positioned on the assembling substrate, such that the light-emitting components, which sink onto the bottom of the bath or float, may be moved toward the assembling substrate by a magnetic force of the magnet.

Meanwhile, an electric field may be formed on the assembling substrate by applying an alternating current voltage. The light-emitting component may have a polarity by being dielectrically polarized by the electric field. Further, the dielectrically polarized light-emitting component may be fixed or moved in a particular direction by dielectrophoresis (DEP), i.e., the electric field. That is, the light-emitting components may be assembled by fixing the plurality of light-emitting components into the grooves of the assembling substrate by using dielectrophoresis.

Therefore, the light-emitting component may include a magnetic element so that the light-emitting component may be moved by a magnetic field. In this case, the content of the magnetic element may be an important factor that determines an assembling rate. That is, the content of the magnetic element may be optimally adjusted to easily move the light-emitting component in accordance with a movement or a movement direction of the magnet, such that an assembling speed and an assembling rate may be improved.

However, because the light-emitting component is miniaturized to a micro-scale, there is a problem in that it is difficult to control the content of the magnetic element. Therefore, it is difficult to optimally adjust the content of the magnetic element and manage the dispersion of the magnetic elements, which may cause an assembling defect. That is, there may occur a flip phenomenon in which the light-emitting components are assembled in a direction opposite to a predetermined direction without being assembled in the predetermined direction during the assembling process. The flip phenomenon may cause a defect in which the light-emitting component is not turned on. In addition, because the light-emitting component is miniaturized to a micro-scale, there may also occur a defect in which the light-emitting component is easily broken during the assembling process.

The light-emitting component LEDa according to the embodiment of the present specification may include the first light-emitting element LED1 and the second light-emitting element LED2 coupled by the bonding layer BDLa. In this case, the first light-emitting element LED1 and the second light-emitting element LED2 may include magnetic elements so as to be autonomously assembled. Meanwhile, the first light-emitting element LED1 and the second light-emitting element LED2 may be shaped symmetrically with respect to the bonding layer BDLa. Therefore, the light-emitting component LEDa may be turned on even though the light-emitting component LEDa is assembled in any direction. For example, in accordance with the assembling direction, the first light-emitting element LED1 may be positioned below the second light-emitting element LED2, or the second light-emitting element LED2 may be positioned below the first light-emitting element LED1. In this case, because the first light-emitting element LED1 and the second light-emitting element LED2 are symmetric, the electrodes disposed at outermost sides of the light-emitting component LEDa may be identical to each other. Therefore, the light-emitting component LEDa may be turned on even though the light-emitting component LEDa is assembled in any direction. That is, in the light-emitting component LEDa according to the embodiment of the present specification, the first light-emitting element LED1 and the second light-emitting element LED2 are shaped symmetrically, such that the light-emitting component LEDa may be assembled in the two directions, which may improve a degree of freedom of assembling directionality of the light-emitting component LEDa.

In addition, in the light-emitting component LEDa according to the embodiment of the present specification, the stacked structures of the first electrodes PE1 and PE2, the first semiconductor layers PL1 and PL2, the active layers EL1 and EL2, the second semiconductor layers NL1 and NL2, and the second electrodes NE1 and NE2 of the first and second light-emitting elements LED1 and LED2 may be opposite to each other. Therefore, the first electrodes PE1 and PE2 may be disposed at the outermost sides regardless of the assembling direction of the light-emitting component LEDa. In this case, the first electrodes PE1 and PE2 may each be made of a transparent material. Therefore, the light emission efficiency may be improved even though the light-emitting component LEDa is assembled in any direction.

In addition, in the light-emitting component LEDa according to the embodiment of the present specification, the first light-emitting element LED1 and the second light-emitting element LED2, which emit light with the same color, may be electrically connected through the bonding layer BDLa. Therefore, the first light-emitting element LED1 and the second light-emitting element LED2 may be simultaneously turned on, thereby implementing high luminance.

In addition, in the light-emitting component LEDa according to the embodiment of the present specification, the first light-emitting element LED1 and the second light-emitting element LED2 may be coupled by the bonding layer BDLa and simultaneously and autonomously assembled. Therefore, the light-emitting component LEDa may be relatively thick in comparison with a case in which only any one of the first light-emitting element LED1 and the second light-emitting element LED2 is autonomously assembled. Therefore, it is possible to minimize or reduce a problem in which the light-emitting component is broken because of a small thickness during the assembling process.

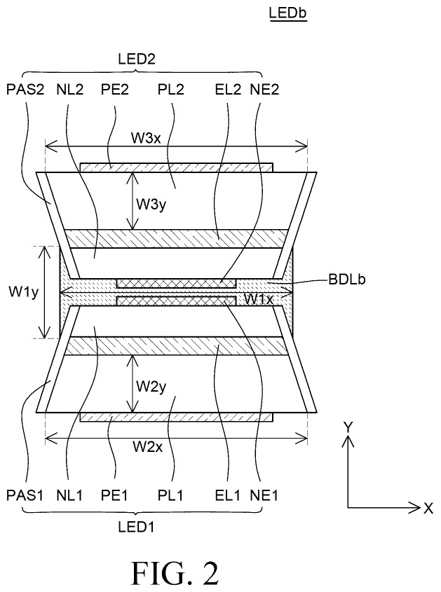

FIG. 2 is a cross-sectional view of a light-emitting component according to another embodiment of the present specification. A light-emitting component LEDb in FIG. 2 is substantially identical in configuration to the light-emitting component LEDa in FIG. 1, except for a bonding layer BDLb. Therefore, repeated descriptions of the identical components will be omitted.

With reference to FIG. 2, the bonding layer BDLb may be disposed on the first light-emitting element LED1. The bonding layer BDLb may be disposed between the first light-emitting element LED1 and the second light-emitting element LED2 and fix the first light-emitting element LED1 and the second light-emitting element LED2. Meanwhile, the bonding layer BDLb may electrically connect the first light-emitting element LED1 and the second light-emitting element LED2 so that the first light-emitting element LED1 and the second light-emitting element LED2 operate simultaneously.

The bonding layer BDLb may be disposed to extend to the side surface of the light-emitting component LEDb, thereby facilitating electrical connection in the display device to be described below. In this case, the bonding layer BDLb may be disposed to extend to the side surfaces of the first and second light-emitting elements LED1 and LED2 to facilitate the electrical connection regardless of the assembling direction of the light-emitting component LEDb. That is, the bonding layer BDLb may be disposed to protrude from the side surfaces of the first and second light-emitting elements LED1 and LED2. Therefore, the bonding layer BDLb may cover partial areas of the passivation films PAS1 and PAS2 that surround the side surface of the light-emitting component LEDb.

The light-emitting component LEDb according to another embodiment of the present specification may include the first light-emitting element LED1 and the second light-emitting element LED2 coupled by the bonding layer BDLb. In this case, the first light-emitting element LED1 and the second light-emitting element LED2 may include magnetic elements so as to be autonomously assembled. Meanwhile, the first light-emitting element LED1 and the second light-emitting element LED2 may be shaped symmetrically with respect to the bonding layer BDLb. Therefore, the light-emitting component LEDb may be turned on even though the light-emitting component LEDb is assembled in any direction. That is, because the first light-emitting element LED1 and the second light-emitting element LED2 are symmetric, the electrodes disposed at outermost sides of the light-emitting component LEDb may be identical to each other. Therefore, the light-emitting component LEDb may be turned on even though the light-emitting component LEDb is assembled in any direction. That is, in the light-emitting component LEDb according to another embodiment of the present specification, the first light-emitting element LED1 and the second light-emitting element LED2 are shaped symmetrically, such that the light-emitting component LEDb may be assembled in the two directions, which may improve a degree of freedom of assembling directionality of the light-emitting component LEDb.

In addition, in the light-emitting component LEDb according to another embodiment of the present specification, the stacked structures of the first electrodes PE1 and PE2, the first semiconductor layers PL1 and PL2, the active layers EL1 and EL2, the second semiconductor layers NL1 and NL2, and the second electrodes NE1 and NE2 of the first and second light-emitting elements LED1 and LED2 may be opposite to each other. Therefore, the first electrodes PE1 and PE2 may be disposed at the outermost sides regardless of the assembling direction of the light-emitting component LEDb. In this case, the first electrodes PE1 and PE2 may each be made of a transparent material. Therefore, the light emission efficiency may be improved even though the light-emitting component LEDb is assembled in any direction.

In addition, in the light-emitting component LEDb according to another embodiment of the present specification, the first light-emitting element LED1 and the second light-emitting element LED2, which emit light with the same color, may be electrically connected through the bonding layer BDLb. Therefore, the first light-emitting element LED1 and the second light-emitting element LED2 may be simultaneously turned on, thereby implementing high luminance.

In addition, in the light-emitting component LEDb according to another embodiment of the present specification, the first light-emitting element LED1 and the second light-emitting element LED2 may be coupled by the bonding layer BDLb and simultaneously and autonomously assembled. Therefore, the light-emitting component LEDb may be relatively thick in comparison with a case in which only any one of the first light-emitting element LED1 and the second light-emitting element LED2 is autonomously assembled. Therefore, it is possible to minimize or reduce a problem in which the light-emitting component is broken because of a small thickness during the assembling process.

In particular, in the light-emitting component LEDb according to another embodiment of the present specification, the bonding layer BDLb is disposed to extend to the side surface of the light-emitting component LEDb, which may facilitate the electrical connection in the display device. In this case, the bonding layer BDLb may be disposed to protrude from the side surfaces of the first and second light-emitting elements LED1 and LED2. Therefore, the coupling properties with the electrode of the display device may be improved regardless of the assembling direction of the light-emitting component LEDb.

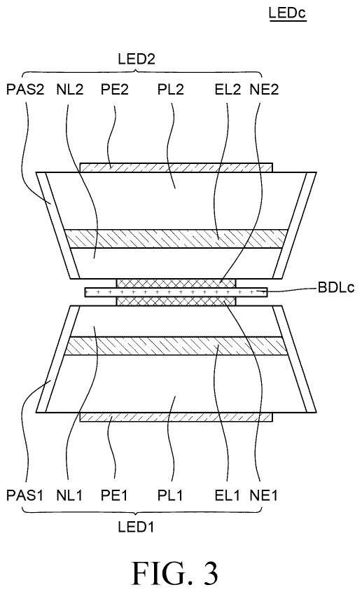

FIG. 3 is a cross-sectional view of a light-emitting component according to still another embodiment of the present specification. A light-emitting component LEDc in FIG. 3 is substantially identical in configuration to the light-emitting component LEDa in FIG. 1, except for a bonding layer BDLc. Therefore, repeated descriptions of the identical components will be omitted.

With reference to FIG. 3, the bonding layer BDLc may be disposed on the first light-emitting element LED1. The bonding layer BDLc may be disposed between the first light-emitting element LED1 and the second light-emitting element LED2 and fix the first light-emitting element LED1 and the second light-emitting element LED2.

The bonding layer BDLc may be made of an insulating material so that the first light-emitting element LED1 and the second light-emitting element LED2 operate independently. That is, the bonding layer BDLc may be disposed between the first light-emitting element LED1 and the second light-emitting element LED2 and insulate the first light-emitting element LED1 and the second light-emitting element LED2. Therefore, the second electrode NE1 of the first light-emitting element LED1 and the second electrode NE2 of the second light-emitting element LED2 may be disposed to be spaced apart from each other by the bonding layer BDLc. Therefore, as described below, in the display device, the first light-emitting element LED1 and the second light-emitting element LED2 may be connected to the same driving transistor and operate together. Of course, the first light-emitting element LED1 and the second light-emitting element LED2 may be connected to different connection electrodes or driving transistors and operated and turned on independently.

The light-emitting component LEDc according to still another embodiment of the present specification may include the first light-emitting element LED1 and the second light-emitting element LED2 coupled by the bonding layer BDLc. In this case, the first light-emitting element LED1 and the second light-emitting element LED2 may include magnetic elements so as to be autonomously assembled. Meanwhile, the first light-emitting element LED1 and the second light-emitting element LED2 may be shaped symmetrically with respect to the bonding layer BDLc. Therefore, the light-emitting component LEDc may be turned on even though the light-emitting component LEDc is assembled in any direction. That is, because the first light-emitting element LED1 and the second light-emitting element LED2 are symmetric, the electrodes disposed at outermost sides of the light-emitting component LEDc may be identical to each other. Therefore, the light-emitting component LEDc may be turned on even though the light-emitting component LEDc is assembled in any direction. That is, in the light-emitting component LEDc according to the embodiment of the present specification, the first light-emitting element LED1 and the second light-emitting element LED2 are shaped symmetrically, such that the light-emitting component LEDc may be assembled in the two directions, which may improve a degree of freedom of assembling directionality of the light-emitting component LEDc.

In addition, in the light-emitting component LEDc according to still another embodiment of the present specification, the stacked structures of the first electrodes PE1 and PE2, the first semiconductor layers PL1 and PL2, the active layers EL1 and EL2, the second semiconductor layers NL1 and NL2, and the second electrodes NE1 and NE2 of the first and second light-emitting elements LED1 and LED2 may be opposite to each other. Therefore, the first electrodes PE1 and PE2 may be disposed at the outermost sides regardless of the assembling direction of the light-emitting component LEDc. In this case, the first electrodes PE1 and PE2 may each be made of a transparent material. Therefore, the light emission efficiency may be improved even though the light-emitting component LEDc is assembled in any direction.

In addition, in the light-emitting component LEDc according to still another embodiment of the present specification, the first light-emitting element LED1 and the second light-emitting element LED2, which emit light with the same color, may be coupled by the bonding layer BDLc. Therefore, the first light-emitting element LED1 and the second light-emitting element LED2 may be simultaneously turned on, thereby implementing high luminance.

In addition, in the light-emitting component LEDc according to still another embodiment of the present specification, the first light-emitting element LED1 and the second light-emitting element LED2 may be coupled by the bonding layer BDLc and simultaneously and autonomously assembled. Therefore, the light-emitting component LEDc may be relatively thick in comparison with a case in which only any one of the first light-emitting element LED1 and the second light-emitting element LED2 is autonomously assembled. Therefore, it is possible to minimize or reduce a problem in which the light-emitting component is broken because of a small thickness during the assembling process.

In particular, in the light-emitting component LEDc according to still another embodiment of the present specification, the bonding layer BDLc disposed between the first light-emitting element LED1 and the second light-emitting element LED2 may be made of an insulating material. That is, the bonding layer BDLc may space the first light-emitting element LED1 and the second light-emitting element LED2 apart while insulating the first light-emitting element LED1 and the second light-emitting element LED2. Therefore, the first light-emitting element LED1 and the second light-emitting element LED2 may operate independently. Therefore, even though the first light-emitting element LED1 is defective, the second light-emitting element LED2 may be operated and turned on. Likewise, even though the second light-emitting element LED2 is defective, the first light-emitting element LED1 may be operated and turned on. That is, even though any one of the first light-emitting element LED1 and the second light-emitting element LED2 is defective, the remaining light-emitting component may be turned on because the first light-emitting element LED1 and the second light-emitting element LED2 operate independently. Therefore, it is possible to suppress a situation in which the light-emitting component LEDc completely becomes a dark spot.

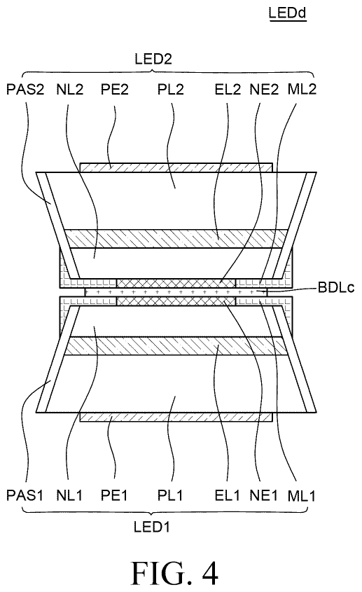

FIG. 4 is a cross-sectional view of a light-emitting component according to yet another embodiment of the present specification. A light-emitting component LEDd in FIG. 4 is substantially identical in configuration to the light-emitting component LEDc in FIG. 3, except for auxiliary electrodes ML1 and ML2. Therefore, repeated descriptions of the identical components will be omitted.

With reference to FIG. 4, the bonding layer BDLc may be made of an insulating material so that the first light-emitting element LED1 and the second light-emitting element LED2 operate independently. That is, the bonding layer BDLc may be disposed between the first light-emitting element LED1 and the second light-emitting element LED2 and insulate the first light-emitting element LED1 and the second light-emitting element LED2. Therefore, the second electrode NE1 of the first light-emitting element LED1 and the second electrode NE2 of the second light-emitting element LED2 may be disposed to be spaced apart from each other by the bonding layer BDLc. Therefore, as described below, in the display device, the first light-emitting element LED1 and the second light-emitting element LED2 may be connected to the same driving transistor and operate together. Of course, the first light-emitting element LED1 and the second light-emitting element LED2 may be connected to different connection electrodes or driving transistors and operated and turned on independently.

The first and second light-emitting elements LED1 and LED2 may respectively include the auxiliary electrodes ML1 and ML2 that surround the second electrodes NE1 and NE2. The auxiliary electrodes ML1 and ML2 may be disposed to extend to a side surface of the light-emitting component LEDd, thereby facilitating the electrical connection in the display device to be described below. In this case, the auxiliary electrodes ML1 and ML2 may be disposed to extend to the side surfaces of the first and second light-emitting elements LED1 and LED2 to facilitate the electrical connection regardless of the assembling direction of the light-emitting component LEDd. That is, the auxiliary electrodes ML1 and ML2 may be disposed to protrude from the side surfaces of the first and second light-emitting elements LED1 and LED2. Therefore, the auxiliary electrodes ML1 and ML2 may cover partial areas of the passivation films PAS1 and PAS2 that surround the side surface of the light-emitting component LEDd.

The auxiliary electrodes ML1 and ML2 may be made of an electrically conductive material so as to be connected to the electrode of the display device. For example, because the auxiliary electrodes ML1 and ML2 are respectively connected to the second electrodes NE1 and NE2 of the light-emitting component LEDd, the auxiliary electrodes ML1 and ML2 may be made of a metallic material capable of being bonded to the second electrodes NE1 and NE2 by eutectic bonding. However, the present specification is not limited thereto.

Meanwhile, FIG. 4 illustrates that the auxiliary electrodes ML1 and ML2 extend from the side surface of the light-emitting component LEDd. However, the present specification is not limited thereto. The second electrodes NE1 and NE2 may be disposed to extend from the side surface of the light-emitting component LEDd. That is, the second electrodes NE1 and NE2 may be disposed to protrude from the side surfaces of the first and second light-emitting elements LED1 and LED2. Therefore, the second electrodes NE1 and NE2 may cover partial areas of the passivation films PAS1 and PAS2 that surround the side surface of the light-emitting component LEDd. However, the present specification is not limited to the configuration illustrated in the drawings.

The light-emitting component LEDd according to yet another embodiment of the present specification may include the first light-emitting element LED1 and the second light-emitting element LED2 coupled by the bonding layer BDLc. In this case, the first light-emitting element LED1 and the second light-emitting element LED2 may include magnetic elements so as to be autonomously assembled. Meanwhile, the first light-emitting element LED1 and the second light-emitting element LED2 may be shaped symmetrically with respect to the bonding layer BDLc. Therefore, the light-emitting component LEDd may be turned on even though the light-emitting component LEDd is assembled in any direction. For example, in accordance with the assembling direction, the first light-emitting element LED1 may be positioned below the second light-emitting element LED2, or the second light-emitting element LED2 may be positioned below the first light-emitting element LED1. In this case, because the first light-emitting element LED1 and the second light-emitting element LED2 are symmetric, the electrodes disposed at outermost sides of the light-emitting component LEDd may be identical to each other. Therefore, the light-emitting component LEDd may be turned on even though the light-emitting component LEDd is assembled in any direction. That is, in the light-emitting component LEDd according to the embodiment of the present specification, the first light-emitting element LED1 and the second light-emitting element LED2 are shaped symmetrically, such that the light-emitting component LEDd may be assembled in the two directions, which may improve a degree of freedom of assembling directionality of the light-emitting component LEDd.

In addition, in the light-emitting component LEDd according to yet another embodiment of the present specification, the stacked structures of the first electrodes PE1 and PE2, the first semiconductor layers PL1 and PL2, the active layers EL1 and EL2, the second semiconductor layers NL1 and NL2, and the second electrodes NE1 and NE2 of the first and second light-emitting elements LED1 and LED2 may be opposite to each other. Therefore, the first electrodes PE1 and PE2 may be disposed at the outermost sides regardless of the assembling direction of the light-emitting component LEDd. In this case, the first electrodes PE1 and PE2 may each be made of a transparent material. Therefore, the light emission efficiency may be improved even though the light-emitting component LEDd is assembled in any direction.

In addition, in the light-emitting component LEDd according to yet another embodiment of the present specification, the first light-emitting element LED1 and the second light-emitting element LED2, which emit light with the same color, may be coupled by the bonding layer BDLc. Therefore, the first light-emitting element LED1 and the second light-emitting element LED2 may be simultaneously turned on, thereby implementing high luminance.

In addition, in the light-emitting component LEDd according to yet another embodiment of the present specification, the first light-emitting element LED1 and the second light-emitting element LED2 may be coupled by the bonding layer BDLc and simultaneously and autonomously assembled. Therefore, the light-emitting component LEDd may be relatively thick in comparison with a case in which only any one of the first light-emitting element LED1 and the second light-emitting element LED2 is autonomously assembled. Therefore, it is possible to minimize or reduce a problem in which the light-emitting component is broken because of a small thickness during the assembling process.

In addition, in the light-emitting component LEDd according to yet another embodiment of the present specification, the bonding layer BDLc disposed between the first light-emitting element LED1 and the second light-emitting element LED2 may be made of an insulating material. That is, the bonding layer BDLc may space the first light-emitting element LED1 and the second light-emitting element LED2 apart while insulating the first light-emitting element LED1 and the second light-emitting element LED2. Therefore, the first light-emitting element LED1 and the second light-emitting element LED2 may operate independently. Therefore, even though the first light-emitting element LED1 is defective, the second light-emitting element LED2 may be operated and turned on. Likewise, even though the second light-emitting element LED2 is defective, the first light-emitting element LED1 may be operated and turned on. That is, even though any one of the first light-emitting element LED1 and the second light-emitting element LED2 is defective, the remaining light-emitting component may be turned on because the first light-emitting element LED1 and the second light-emitting element LED2 operate independently. Therefore, it is possible to suppress a situation in which the light-emitting component LEDd completely becomes a dark spot.

In particular, in the light-emitting component LEDd according to yet another embodiment of the present specification, the auxiliary electrodes ML1 and ML2 may be disposed to surround the second electrodes NE1 and NE2. The auxiliary electrodes ML1 and ML2 may be disposed to extend to the side surface of the light-emitting component LEDd, thereby facilitating the electrical connection in the display device. In this case, the auxiliary electrodes ML1 and ML2 may be disposed to protrude from the side surfaces of the first and second light-emitting elements LED1 and LED2. Therefore, the coupling properties with the electrode of the display device may be improved regardless of the assembling direction of the light-emitting component LEDd.

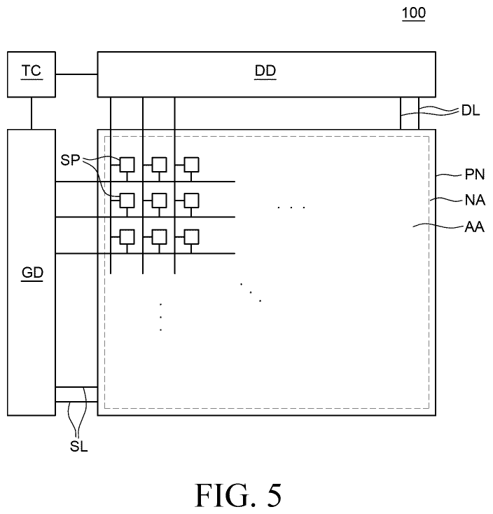

Hereinafter, the display device including the light-emitting component according to various embodiments of the present specification will be described in detail with reference to FIGS. 5 to 14.

FIG. 5 is a schematic configuration view of the display device according to the embodiment of the present specification. For convenience of description, FIG. 5 illustrates only a display panel PN, a gate driver GD, a data driver DD, and a timing controller TC among various constituent elements of a display device 100.

The gate driver GD supplies a plurality of scan signals to a plurality of scan lines SL in response to a plurality of gate control signals provided from the timing controller TC. FIG. 5 illustrates that the single gate driver GD is disposed to be spaced apart from one side of the display panel PN. However, the number and arrangement of the gate driver GD are not limited thereto.

The data driver DD converts image data, which are inputted from the timing controller TC, into a data voltage by using a reference gamma voltage in response to a plurality of data control signals provided from the timing controller TC. The data driver DD may supply the converted data voltage to a plurality of data lines DL.

The timing controller TC aligns image data, which are inputted from the outside, and supplies the image data to the data driver DD. The timing controller TC may generate the gate control signals and the data control signals by using synchronizing signals, i.e., dot clock signals, data enable signals, and horizontal/vertical synchronizing signals inputted from the outside. Further, the timing controller TC may control the gate driver GD and the data driver DD by supplying the generated gate control signals and data control signals to the gate driver GD and the data driver DD.

The display panel PN is configured to display images to a user and includes the plurality of subpixels SP. In the display panel PN, the plurality of scan lines SL, and the plurality of data lines DL intersect one another, and each of the plurality of subpixels SP is connected to the scan line SL and the data line DL. In addition, although not illustrated in the drawings, the plurality of subpixels SP may be respectively connected to a high-potential power line, a low-potential power line, a reference line, and the like.

The display panel PN may have a display area AA, and a non-display area NA configured to surround the display area AA.

The display area AA is an area of the display device 100 in which images are displayed. The display area AA may include a plurality of subpixels SP constituting a plurality of pixels, and a circuit configured to operate the plurality of subpixels SP. The plurality of subpixels SP is minimum units that constitute the display area AA. The n subpixels SP may constitute a single pixel. A light-emitting component, a thin-film transistor for operating the light-emitting component, and the like may be disposed in each of the plurality of subpixels SP. The plurality of light-emitting components may be differently defined depending on the type of the display panel PN. For example, in case that the display panel PN is an inorganic light-emitting display panel, the light-emitting component may be a light-emitting diode (LED) or a micro light-emitting diode (micro LED).

A plurality of lines for transmitting various types of signals to the plurality of subpixels SP is disposed in the display area AA. For example, the plurality of lines may include the plurality of data lines DL for supplying data voltages to the plurality of subpixels SP, and the plurality of scan lines SL for supplying scan signals to the plurality of subpixels SP. The plurality of scan lines SL may extend in one direction in the display area AA and be connected to the plurality of subpixels SP. The plurality of data lines DL may extend in a direction different from one direction in the display area AA and be connected to the plurality of subpixels SP. In addition, a low-potential power line, a high-potential power line, and the like may be further disposed in the display area AA. However, the present specification is not limited thereto.

The non-display area NA may be defined as an area in which no image is displayed, i.e., an area extending from the display area AA. The non-display area NA may include link lines and pad electrodes for transmitting signals to the subpixels SP in the display area AA. Alternatively, the non-display area NA may include drive ICs such as gate drivers IC and data drivers IC.

However, the non-display area NA may be positioned on a rear surface of the display panel PN, i.e., a surface on which the subpixel SP is not present. Alternatively, the non-display area NA may be excluded. However, the present specification is not limited to the configuration illustrated in the drawings.

Meanwhile, the drivers such as the gate driver GD, the data driver DD, and the timing controller TC may be connected to the display panel PN in various ways. For example, the gate driver GD may be mounted in the non-display area NA by a gate-in-panel (GIP) method or mounted between the plurality of subpixels SP by a gate-in-active area (GIA) method in the display area AA. For example, the data driver DD and the timing controller TC may be formed on a separate flexible film and the printed circuit board PCB. The data driver DD and the timing controller TC may be electrically connected to the display panel PN by bonding the flexible film and the printed circuit board PCB to the pad electrode formed in the non-display area NA of the display panel PN.

In case that the gate driver GD is mounted by the GIP method and the data driver DD and the timing controller TC transmit signals to the display panel PN through the pad electrode in the non-display area NA, it is necessary to ensure an area of the non-display area NA at a predetermined level or higher in order to dispose the gate driver GD and the pad electrode, which may increase a bezel.

Alternatively, in case that the gate driver GD is mounted in the display area AA by the GIA method and a side line, which connects a signal line on a front surface of the display panel PN to the pad electrode on the rear surface of the display panel PN, is formed to bond the flexible film and the printed circuit board to the rear surface of the display panel PN, it is possible to minimize or reduce the non-display area NA on the front surface of the display panel PN. That is, in case that the gate driver GD, the data driver DD, and the timing controller TC are connected to the display panel PN by the above-mentioned method, a zero bezel in which the bezel is not substantially present may be implemented.

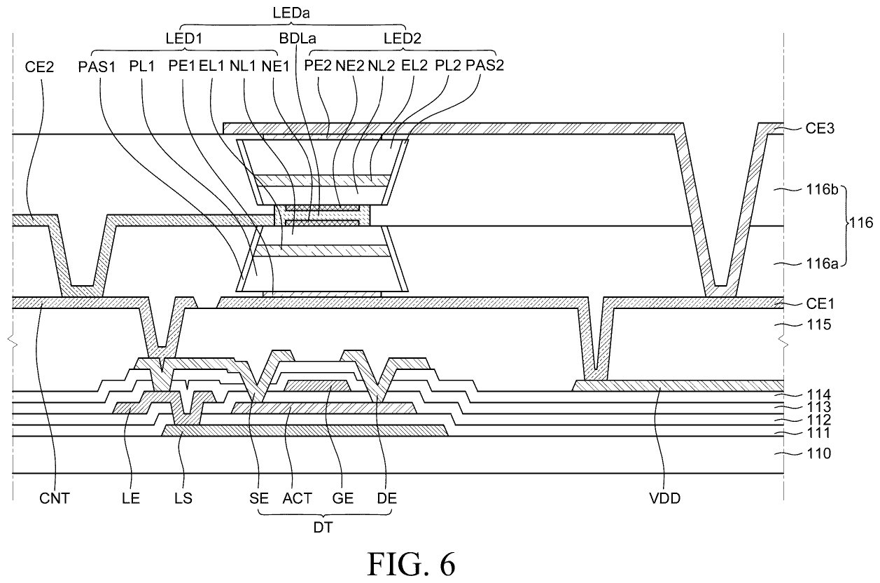

Hereinafter, one subpixel SP of the display device 100 according to the embodiment of the present specification will be described with reference to FIG. 6.

FIG. 6 is a cross-sectional view of one subpixel of the display device according to the embodiment of the present specification.

With reference to FIG. 6, the plurality of subpixels SP of the display panel PN of the display device 100 according to the embodiment of the present specification may each include a substrate 110, a buffer layer 111, a gate insulation layer 112, a first interlayer insulation layer 113, a second interlayer insulation layer 114, an overcoating layer 115, a planarization layer 116, a driving transistor DT, the light-emitting component LEDa, an intermediate electrode CNT, a light-blocking layer LS, an auxiliary electrode LE, a first connection electrode CE1, a second connection electrode CE2, and a third connection electrode CE3.

First, the substrate 110 is a component for supporting various constituent elements included in the display device 100 and may be made of an insulating material. For example, the substrate 110 may be made of glass, resin, or the like. In addition, the substrate 110 may include plastic such as polymer and may be made of a material having flexibility.

The light-blocking layer LS may be disposed on each of the plurality of subpixels SP on the substrate 110. The light-blocking layer LS blocks light entering an active layer ACT of the driving transistor DT, which will be described below, from a lower side of the substrate 110. The light-blocking layer LS may block light entering the active layer ACT of the driving transistor DT, thereby minimizing or reducing a leakage current.

The buffer layer 111 is disposed on the substrate 110 and the light-blocking layer LS. The buffer layer 111 may reduce the penetration of moisture or impurities through the substrate 110. For example, the buffer layer 111 may be configured as a single layer or multilayer made of silicon oxide (SiOx) or silicon nitride (SiNx). However, the present specification is not limited thereto. However, the buffer layer 111 may be excluded in accordance with the type of substrate 110 or the type of transistor. However, the present specification is not limited thereto.

The driving transistor DT is disposed on the buffer layer 111. The driving transistor DT includes the active layer ACT, a gate electrode GE, a source electrode SE, and a drain electrode DE.

The active layer ACT may be disposed on the buffer layer 111. The active layer ACT may be made of a semiconductor material such as an oxide semiconductor, amorphous silicon, or polysilicon. However, the present specification is not limited thereto.

The gate insulation layer 112 may be disposed on the active layer ACT. The gate insulation layer 112 is an insulation layer for insulating the active layer ACT and the gate electrode GE. The gate insulation layer 112 may be configured as a single layer or multilayer made of silicon oxide (SiOx) or silicon nitride (SiNx). However, the present specification is not limited thereto.

The gate electrode GE may be disposed on the gate insulation layer 112. The gate electrode GE may be made of an electrically conductive material, for example, copper (Cu), aluminum (Al), molybdenum (Mo), nickel (Ni), titanium (Ti), chromium (Cr), or an alloy thereof. However, the present specification is not limited thereto.

The first interlayer insulation layer 113 and the second interlayer insulation layer 114 may be disposed on the gate electrode GE. Contact holes, through which the source electrode SE and the drain electrode DE are connected to the active layer ACT, are formed in the first interlayer insulation layer 113 and the second interlayer insulation layer 114. The first interlayer insulation layer 113 and the second interlayer insulation layer 114 may be insulation layers for protecting components disposed below the first interlayer insulation layer 113 and components disposed below the second interlayer insulation layer 114 and each configured as a single layer or multilayer made of silicon oxide (SiOx) or silicon nitride (SiNx). However, the present specification is not limited thereto.

The source electrode SE and the drain electrode DE, which are electrically connected to the active layer ACT, may be disposed on the second interlayer insulation layer 114. The source electrode SE and the drain electrode DE may each be made of an electrically conductive material, for example, copper (Cu), aluminum (Al), molybdenum (Mo), nickel (Ni), titanium (Ti), chromium (Cr), or an alloy thereof. However, the present specification is not limited thereto.

Meanwhile, in the present specification, the configuration has been described in which the first interlayer insulation layer 113 and the second interlayer insulation layer 114, i.e., the plurality of insulation layers is disposed between the gate electrode GE, the source electrode SE, and the drain electrode DE. However, only a single insulation layer may be disposed between the gate electrode GE, the source electrode SE, and the drain electrode DE. However, the present specification is not limited thereto.

Further, as illustrated in the drawings, in case that the plurality of insulation layers, such as the first interlayer insulation layer 113 and the second interlayer insulation layer 114, is disposed between the gate electrode GE, the source electrode SE, and the drain electrode DE, an electrode may be additionally formed between the first interlayer insulation layer 113 and the second interlayer insulation layer 114. The additionally formed electrode may define a capacitor together with other components disposed on the lower portion of the first interlayer insulation layer 113 or the upper portion of the second interlayer insulation layer 114.

The sub-electrode LE may be disposed on the gate insulation layer 112. The sub-electrode LE is an electrode that electrically connects the light-blocking layer LS, which is disposed below the buffer layer 111, to any one of the source electrode SE and the drain electrode DE on the second interlayer insulation layer 114. For example, the light-blocking layer LS may be electrically connected to any one of the source electrode SE or the drain electrode DE through the sub-electrode LE so as not to be operated as a floating gate, thereby minimizing or reducing a change in threshold voltage of the transistor DT caused by the floating light-blocking layer LS. The drawing illustrates that the light-blocking layer LS is connected to the source electrode SE. However, the light-blocking layer LS may be connected to the drain electrode DE. However, the present specification is not limited thereto.

A power line VDD may be disposed on the second interlayer insulation layer 114. The power line VDD may be electrically connected to the light-emitting component LEDa together with the driving transistor DT and allow a light-emitting component LEDa to emit light. The power line VDD may transmit a high-potential power voltage to the light-emitting component LEDa. However, the present specification is not limited thereto. The power line VDD may be made of an electrically conductive material, for example, copper (Cu), aluminum (Al), molybdenum (Mo), nickel (Ni), titanium (Ti), chromium (Cr), or an alloy thereof. However, the present specification is not limited thereto.

The overcoating layer 115 is disposed on the driving transistor DT and the power line VDD. The overcoating layer 115 may planarize an upper portion of the substrate 110 on which the driving transistor DT is disposed. The overcoating layer 115 may be configured as a single layer or multilayer and made of a photoresist or an acrylic-based organic material, for example. However, the present specification is not limited thereto.

The intermediate electrode CNT and the first connection electrode CE1, which are spaced apart from each other, may be disposed on the overcoating layer 115.

The intermediate electrode CNT may electrically connect the light-emitting component LEDa to the driving transistor DT. The intermediate electrode CNT may be connected to the source electrode SE or the drain electrode DE of the driving transistor DT through a contact hole formed in the overcoating layer 115. Further, the intermediate electrode CNT may be electrically connected to the second electrode NE1 of the first light-emitting element LED1 through the second connection electrode CE2.

In addition, the intermediate electrode CNT may also serve as a reflective plate configured to reflect the light, which is emitted from the light-emitting component LEDa, toward the upper portion of the light-emitting component LEDa. The intermediate electrode CNT may be made of an electrically conductive material having excellent reflection performance and reflect the light, which is emitted from the light-emitting component LEDa, toward the upper portion of the light-emitting component LEDa.

The first connection electrode CE1 may electrically connect the light-emitting component LEDa to the power line VDD. The first connection electrode CE1 may be connected to the power line VDD through a contact hole formed in the overcoating layer 115. Specifically, the first connection electrode CE1 may electrically connect the first electrode PE1 of the first light-emitting element LED1 and the power line VDD.

In addition, the first connection electrode CE1 may also serve as a reflective plate configured to reflect the light, which is emitted from the light-emitting component LEDa, toward the upper portion of the light-emitting component LEDa. The first connection electrode CE1 may be made of an electrically conductive material having excellent reflection performance and reflect the light, which is emitted from the light-emitting component LEDa, toward the upper portion of the light-emitting component LEDa.

The plurality of light-emitting components LEDa may be disposed on the overcoating layer 115 and the first connection electrode CE1 in each of the plurality of subpixels SP. The light-emitting component LEDa may be electrically connected to the power line VDD through the first connection electrode CE1 and the third connection electrode CE3, electrically connected to the transistor DT through the second connection electrode CE2, and operate.

The planarization layer 116 may be disposed on the overcoating layer 115, the intermediate electrode CNT, and the first connection electrode CE1. The planarization layer 116 may be disposed to surround a part of the side surface of the light-emitting component LEDa and fix and protect the plurality of light-emitting components LEDa.

Meanwhile, the planarization layer 116 may be configured as a multilayer, such that the second connection electrode CE2 and the third connection electrode CE3 may be disposed on different layers.

Specifically, a first planarization layer 116a may be disposed on the overcoating layer 115, the intermediate electrode CNT, and the first connection electrode CE1. The first planarization layer 116a may be disposed to surround a part of the side surface of the first light-emitting element LED1 of the light-emitting component LEDa. The first planarization layer 116a may be configured as a single layer or multilayer and made of benzocyclobutene or an acrylic-based organic material, for example. However, the present specification is not limited thereto.

The second connection electrode CE2 may be disposed on the first planarization layer 116a. The second connection electrode CE2 is an electrode for electrically connecting the light-emitting component LEDa and the transistor DT. The second connection electrode CE2 may be disposed on the first planarization layer 116a and connected to the intermediate electrode CNT through contact holes formed in the first planarization layer 116a. Therefore, the second connection electrode CE2 may be electrically connected to the driving transistor DT through the intermediate electrode CNT. Specifically, the second connection electrode CE2 may be in direct contact with the bonding layer BDLa. Therefore, the second connection electrode CE2 may electrically connect the second electrode NE1 of the first light-emitting element LED1, the second electrode NE2 of the second light-emitting element LED2, and the transistor DT through the bonding layer BDLa.

A second planarization layer 116b may be disposed on the first planarization layer 116a and the second connection electrode CE2. The second planarization layer 116b may be disposed to surround a part of the side surface of the first light-emitting element LED1 of the light-emitting component LEDa and the side and top surfaces of the second light-emitting element LED2. Meanwhile, the second planarization layer 116b may be disposed to expose the first electrode PE2 of the second light-emitting element LED2 to electrically connect the plurality of light-emitting components LEDa and the third connection electrode CE3 to be described below. For example, the second planarization layer 116b may be made of benzocyclobutene or an acrylic-based organic material, for example. However, the present specification is not limited thereto.

The third connection electrode CE3 may be disposed on the second planarization layer 116b. The third connection electrode CE3 is an electrode for electrically connecting the second light-emitting element LED2 of the light-emitting component LEDa and the power line VDD. The third connection electrode CE3 may be disposed on the second planarization layer 116b and connected to the first connection electrode CE1 through contact holes formed in the first planarization layer 116a and the second planarization layer 116b. Therefore, the third connection electrode CE3 may be electrically connected to the power line VDD through the first connection electrode CE1. Specifically, the third connection electrode CE3 may electrically connect the first electrode PE2 of the second light-emitting element LED2 and the power line VDD.

In the display device 100 according to the embodiment of the present specification, the light-emitting component LEDa may include the first light-emitting element LED1 and the second light-emitting element LED2 coupled by the bonding layer BDLa. In this case, the first light-emitting element LED1 and the second light-emitting element LED2 may include magnetic elements so as to be autonomously assembled. Meanwhile, the first light-emitting element LED1 and the second light-emitting element LED2 may be shaped symmetrically with respect to the bonding layer BDLa. Therefore, the light-emitting component LEDa may be turned on even though the light-emitting component LEDa is assembled in any direction. For example, in accordance with the assembling direction, the first light-emitting element LED1 may be positioned below the second light-emitting element LED2, or the second light-emitting element LED2 may be positioned below the first light-emitting element LED1. In this case, because the first light-emitting element LED1 and the second light-emitting element LED2 are symmetric, the electrodes disposed at outermost sides of the light-emitting component LEDa may be identical to each other. Therefore, the light-emitting component LEDa may be turned on even though the light-emitting component LEDa is assembled in any direction. That is, in the display device 100 according to the embodiment of the present specification, the first light-emitting element LED1 and the second light-emitting element LED2 are shaped symmetrically, such that the light-emitting component LEDa may be assembled in the two directions, which may improve a degree of freedom of assembling directionality of the light-emitting component LEDa.

In addition, in the display device 100 according to the embodiment of the present specification, the stacked structures of the first electrodes PE1 and PE2, the first semiconductor layers PL1 and PL2, the active layers EL1 and EL2, the second semiconductor layers NL1 and NL2, and the second electrodes NE1 and NE2 of the first and second light-emitting elements LED1 and LED2 may be opposite to each other. Therefore, the first electrodes PE1 and PE2 may be disposed at the outermost sides regardless of the assembling direction of the light-emitting component LEDa. In this case, the first electrodes PE1 and PE2 may each be made of a transparent material. Therefore, the light emission efficiency may be improved even though the light-emitting component LEDa is assembled in any direction.

In addition, in the display device 100 according to the embodiment of the present specification, the first light-emitting element LED1 and the second light-emitting element LED2, which emit light with the same color, may be electrically connected through the bonding layer BDLa. Therefore, the first light-emitting element LED1 and the second light-emitting element LED2 may be simultaneously turned on, thereby implementing high luminance.

In addition, in the display device 100 according to the embodiment of the present specification, the first light-emitting element LED1 and the second light-emitting element LED2 may be coupled by the bonding layer BDLa and simultaneously and autonomously assembled. Therefore, the light-emitting component LEDa may be relatively thick in comparison with a case in which only any one of the first light-emitting element LED1 and the second light-emitting element LED2 is autonomously assembled. Therefore, it is possible to minimize or reduce a problem in which the light-emitting component is broken because of a small thickness during the assembling process.

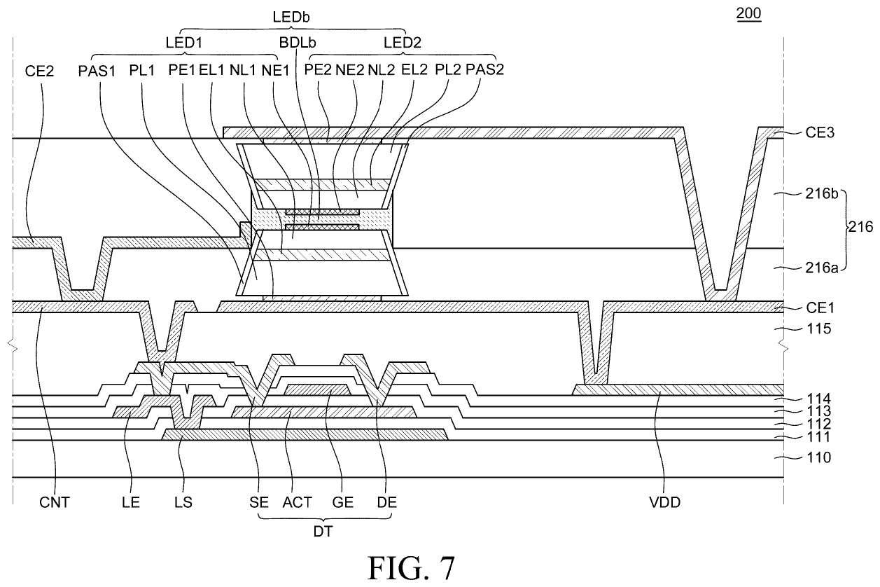

FIG. 7 is a cross-sectional view of a display device according to another embodiment of the present specification. A display device 200 in FIG. 7 is substantially identical in configuration to the display device 100 in FIGS. 5 and 6, except for the light-emitting component LEDb and a planarization layer 216. Therefore, repeated descriptions of the identical components will be omitted.

With reference to FIG. 7, the plurality of light-emitting components LEDb may be disposed on the overcoating layer 115 and the first connection electrode CE1 in each of the plurality of subpixels SP. The light-emitting component LEDb may be electrically connected to the power line VDD through the first connection electrode CE1 and the third connection electrode CE3, electrically connected to the driving transistor DT through the second connection electrode CE2, and operate.

The bonding layer BDLb may be disposed on the first light-emitting element LED1 of the light-emitting component LEDb. The bonding layer BDLb may be disposed between the first light-emitting element LED1 and the second light-emitting element LED2 and fix the first light-emitting element LED1 and the second light-emitting element LED2. Meanwhile, the bonding layer BDLb may electrically connect the first light-emitting element LED1 and the second light-emitting element LED2 so that the first light-emitting element LED1 and the second light-emitting element LED2 operate simultaneously.

The bonding layer BDLb may be disposed to extend to the side surface of the light-emitting component LEDb, thereby facilitating the electrical connection with the second connection electrode CE2. In this case, the bonding layer BDLb may be disposed to extend to the side surfaces of the first and second light-emitting elements LED1 and LED2 to facilitate the electrical connection regardless of the assembling direction of the light-emitting component LEDb. That is, the bonding layer BDLb may be disposed to protrude from the side surfaces of the first and second light-emitting elements LED1 and LED2. Therefore, the bonding layer BDLb may cover partial areas of the passivation films PAS1 and PAS2 that surround the side surface of the light-emitting component LEDb.

A first planarization layer 216a may be disposed on the overcoating layer 115, the intermediate electrode CNT, and the first connection electrode CE1 to surround a part of the side surface of the light-emitting component LEDb. The first planarization layer 216a may be disposed in a range in which the first planarization layer 216a does not overlap the bonding layer BDLb so that the first planarization layer 216a connects the bonding layer BDLb and the second connection electrode CE2. Therefore, a height of the first planarization layer 216a may be relatively low in comparison with a case in which the bonding layer BDLb is not disposed to extend. However, the present specification is not limited thereto.

The second connection electrode CE2 may be disposed on the first planarization layer 216a. The second connection electrode CE2 is an electrode for electrically connecting the light-emitting component LEDb and the transistor DT. The second connection electrode CE2 may be disposed on the first planarization layer 216a and connected to the intermediate electrode CNT through the contact hole formed in the first planarization layer 216a. Therefore, the second connection electrode CE2 may be electrically connected to the transistor DT through the intermediate electrode CNT.

Specifically, the second connection electrode CE2 may be in direct contact with the bonding layer BDLb. Therefore, the second connection electrode CE2 may electrically connect the second electrode NE1 of the first light-emitting element LED1, the second electrode NE2 of the second light-emitting element LED2, and the driving transistor DT through the bonding layer BDLb. In this case, because the bonding layer BDLb is disposed to extend to the side surface of the light-emitting component LEDb, the second connection electrode CE2 may be easily in contact with the bonding layer BDLb and thus easily electrically connected to the second electrodes NE1 and NE2.

In the display device 200 according to another embodiment of the present specification, the light-emitting component LEDb may include the first light-emitting element LED1 and the second light-emitting element LED2 coupled by the bonding layer BDLb. In this case, the first light-emitting element LED1 and the second light-emitting element LED2 may include magnetic elements so as to be autonomously assembled. Meanwhile, the first light-emitting element LED1 and the second light-emitting element LED2 may be shaped symmetrically with respect to the bonding layer BDLb. Therefore, the light-emitting component LEDb may be turned on even though the light-emitting component LEDb is assembled in any direction. For example, in accordance with the assembling direction, the first light-emitting element LED1 may be positioned below the second light-emitting element LED2, or the second light-emitting element LED2 may be positioned below the first light-emitting element LED1. In this case, because the first light-emitting element LED1 and the second light-emitting element LED2 are symmetric, the electrodes disposed at outermost sides of the light-emitting component LEDb may be identical to each other. Therefore, the light-emitting component LEDb may be turned on even though the light-emitting component LEDb is assembled in any direction. That is, in the display device 200 according to the embodiment of the present specification, the first light-emitting element LED1 and the second light-emitting element LED2 are shaped symmetrically, such that the light-emitting component LEDb may be assembled in the two directions, which may improve a degree of freedom of assembling directionality of the light-emitting component LEDb.

In addition, in the display device 200 according to another embodiment of the present specification, the stacked structures of the first electrodes PE1 and PE2, the first semiconductor layers PL1 and PL2, the active layers EL1 and EL2, the second semiconductor layers NL1 and NL2, and the second electrodes NE1 and NE2 of the first and second light-emitting elements LED1 and LED2 may be opposite to each other. Therefore, the first electrodes PE1 and PE2 may be disposed at the outermost sides regardless of the assembling direction of the light-emitting component LEDb. In this case, the first electrodes PE1 and PE2 may each be made of a transparent material. Therefore, the light emission efficiency may be improved even though the light-emitting component LEDb is assembled in any direction.

In addition, in the display device 200 according to another embodiment of the present specification, the first light-emitting element LED1 and the second light-emitting element LED2, which emit light with the same color, may be electrically connected through the bonding layer BDLb. Therefore, the first light-emitting element LED1 and the second light-emitting element LED2 may be simultaneously turned on, thereby implementing high luminance.

In addition, in the display device 200 according to another embodiment of the present specification, the first light-emitting element LED1 and the second light-emitting element LED2 may be coupled by the bonding layer BDLb and simultaneously and autonomously assembled. Therefore, the light-emitting component LEDb may be relatively thick in comparison with a case in which only any one of the first light-emitting element LED1 and the second light-emitting element LED2 is autonomously assembled. Therefore, it is possible to minimize or reduce a problem in which the light-emitting component is broken because of a small thickness during the assembling process.

In particular, in the display device 200 according to another embodiment of the present specification, the second connection electrode CE2 may be in direct contact with the bonding layer BDLb of the light-emitting component LEDb and connect the second electrodes NE1 and NE2 of the light-emitting component LEDb to the driving transistor DT. In this case, the bonding layer BDLb of the light-emitting component LEDb may be disposed to extend to the side surface of the light-emitting component LEDb, thereby facilitating the electrical connection with the second connection electrode CE2. In this case, the bonding layer BDLb may be disposed to protrude from the side surfaces of the first and second light-emitting elements LED1 and LED2. Therefore, the coupling properties with the second connection electrode CE2 may be improved regardless of the assembling direction of the light-emitting component LEDb.

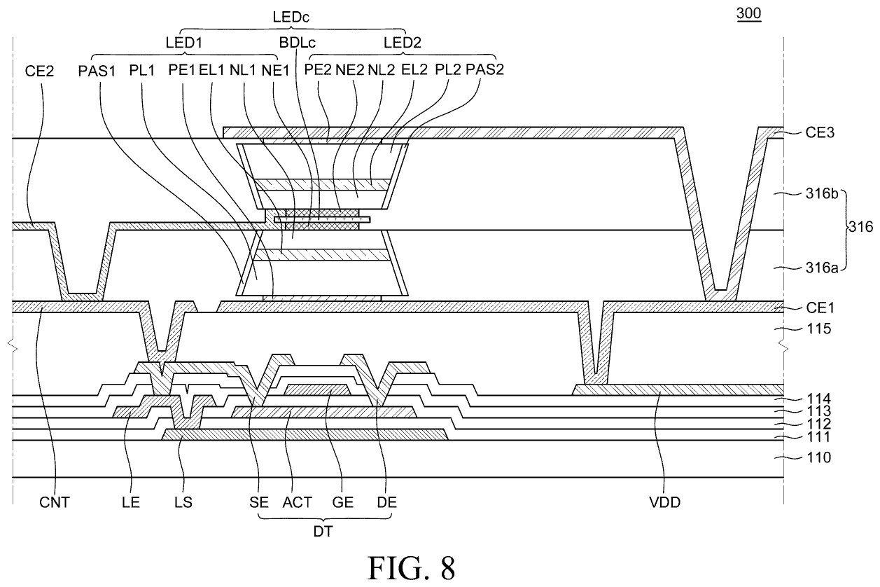

FIG. 8 is a cross-sectional view of a display device according to still another embodiment of the present specification. A display device 300 in FIG. 8 is substantially identical in configuration to the display device 100 in FIGS. 5 and 6, except for the light-emitting component LEDc and the second connection electrode CE2. Therefore, repeated descriptions of the identical components will be omitted.

With reference to FIG. 8, the bonding layer BDLc may be disposed on the first light-emitting element LED1. The bonding layer BDLc may be disposed between the first light-emitting element LED1 and the second light-emitting element LED2 and fix the first light-emitting element LED1 and the second light-emitting element LED2.

The bonding layer BDLc may be made of an insulating material so that the first light-emitting element LED1 and the second light-emitting element LED2 operate independently. That is, the bonding layer BDLc may be disposed between the first light-emitting element LED1 and the second light-emitting element LED2 and insulate the first light-emitting element LED1 and the second light-emitting element LED2. Therefore, the second electrode NE1 of the first light-emitting element LED1 and the second electrode NE2 of the second light-emitting element LED2 may be disposed to be spaced apart from each other by the bonding layer BDLc. Therefore, the first light-emitting element LED1 and the second light-emitting element LED2 may be connected to the same connection electrode and operate together. Of course, the first light-emitting element LED1 and the second light-emitting element LED2 may be connected to different connection electrodes and operated and turned on independently.

The second connection electrode CE2 may be disposed on a first planarization layer 316a. The second connection electrode CE2 is an electrode for electrically connecting the light-emitting component LEDc and the transistor DT. The second connection electrode CE2 may be disposed on the first planarization layer 316a and connected to the intermediate electrode CNT through a contact hole formed in the first planarization layer 316a. Therefore, the second connection electrode CE2 may be electrically connected to the transistor DT through the intermediate electrode CNT.

In this case, the second connection electrode CE2 may be connected to both the second electrode NE1 of the first light-emitting element LED1 and the second electrode NE2 of the second light-emitting element LED2. That is, the second connection electrode CE2 may electrically connect the second electrode NE1 of the first light-emitting element LED1, the second electrode NE2 of the second light-emitting element LED2, and the transistor DT. Therefore, the first light-emitting element LED1 and the second light-emitting element LED2 may operate together by means of the second connection electrode CE2.

In the display device 300 according to still another embodiment of the present specification, the light-emitting component LEDc may include the first light-emitting element LED1 and the second light-emitting element LED2 coupled by the bonding layer BDLc. In this case, the first light-emitting element LED1 and the second light-emitting element LED2 may include magnetic elements so as to be autonomously assembled. Meanwhile, the first light-emitting element LED1 and the second light-emitting element LED2 may be shaped symmetrically with respect to the bonding layer BDLc. Therefore, the light-emitting component LEDc may be turned on even though the light-emitting component LEDc is assembled in any direction. That is, because the first light-emitting element LED1 and the second light-emitting element LED2 are symmetric, the electrodes disposed at outermost sides of the light-emitting component LEDc may be identical to each other. Therefore, the light-emitting component LEDc may be turned on even though the light-emitting component LEDc is assembled in any direction. That is, in the display device 300 according to still another embodiment of the present specification, the first light-emitting element LED1 and the second light-emitting element LED2 are shaped symmetrically, such that the light-emitting component LEDc may be assembled in the two directions, which may improve a degree of freedom of assembling directionality of the light-emitting component LEDc.

In addition, in the display device 300 according to still another embodiment of the present specification, the stacked structures of the first electrodes PE1 and PE2, the first semiconductor layers PL1 and PL2, the active layers EL1 and EL2, the second semiconductor layers NL1 and NL2, and the second electrodes NE1 and NE2 of the first and second light-emitting elements LED1 and LED2 may be opposite to each other. Therefore, the first electrodes PE1 and PE2 may be disposed at the outermost sides regardless of the assembling direction of the light-emitting component LEDc. In this case, the first electrodes PE1 and PE2 may each be made of a transparent material. Therefore, the light emission efficiency may be improved even though the light-emitting component LEDc is assembled in any direction.

In addition, in the display device 300 according to still another embodiment of the present specification, the first light-emitting element LED1 and the second light-emitting element LED2, which emit light with the same color, may be coupled by the bonding layer BDLc. Therefore, the first light-emitting element LED1 and the second light-emitting element LED2 may be simultaneously turned on, thereby implementing high luminance.

In addition, in the display device 300 according to still another embodiment of the present specification, the first light-emitting element LED1 and the second light-emitting element LED2 may be coupled by the bonding layer BDLc and simultaneously and autonomously assembled. Therefore, the light-emitting component LEDc may be relatively thick in comparison with a case in which only any one of the first light-emitting element LED1 and the second light-emitting element LED2 is autonomously assembled. Therefore, it is possible to minimize or reduce a problem in which the light-emitting component is broken because of a small thickness during the assembling process.

In particular, in the display device 300 according to still another embodiment of the present specification, the bonding layer BDLc disposed between the first light-emitting element LED1 and the second light-emitting element LED2 may be made of an insulating material. That is, the bonding layer BDLc may space the first light-emitting element LED1 and the second light-emitting element LED2 apart while insulating the first light-emitting element LED1 and the second light-emitting element LED2. Therefore, the first light-emitting element LED1 and the second light-emitting element LED2 may operate together or may, of course, operate independently. In this case, the second connection electrode CE2 may be connected to both the second electrode NE1 of the first light-emitting element LED1 and the second electrode NE2 of the second light-emitting element LED2. Therefore, the first light-emitting element LED1 and the second light-emitting element LED2 may operate simultaneously.

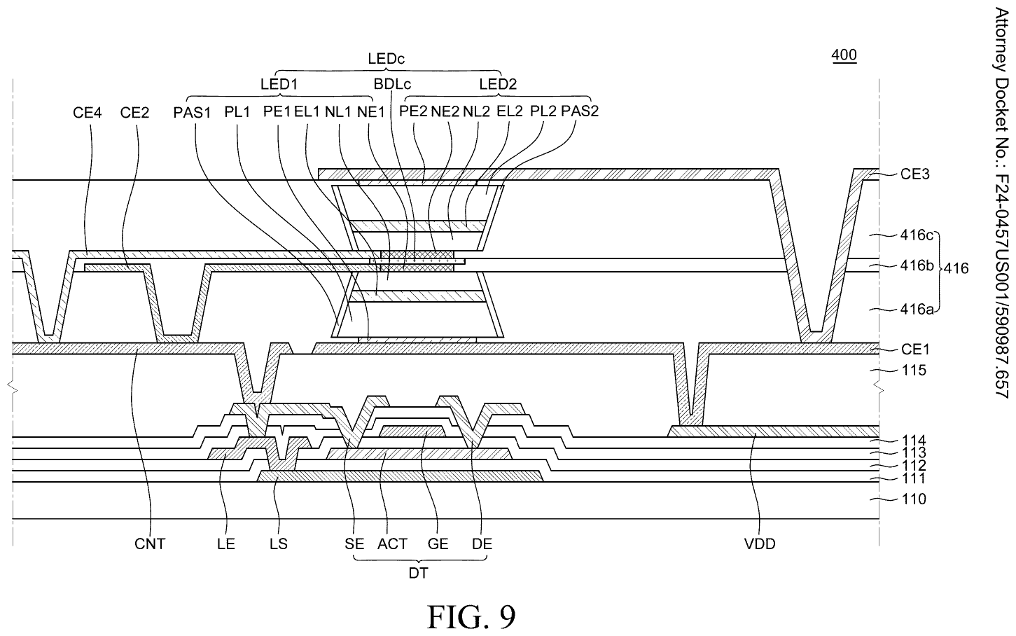

FIG. 9 is a cross-sectional view of a display device according to yet another embodiment of the present specification. A display device 400 in FIG. 9 is substantially identical in configuration to the display device 300 in FIG. 8, except for the second connection electrode CE2, a fourth connection electrode CE4, and a planarization layer 416. Therefore, repeated descriptions of the identical components will be omitted.

With reference to FIG. 9, the second connection electrode CE2 may be disposed on a first planarization layer 416a. The second connection electrode CE2 is an electrode for electrically connecting the light-emitting component LEDc and the driving transistor DT. Specifically, the second connection electrode CE2 is an electrode for electrically connecting the second electrode NE1 of the first light-emitting element LED1 and the driving transistor DT. The second connection electrode CE2 may be disposed on the first planarization layer 416a and connected to the intermediate electrode CNT through a contact hole formed in the first planarization layer 416a. Therefore, the second connection electrode CE2 may be electrically connected to the driving transistor DT through the intermediate electrode CNT.

A second planarization layer 416b may be disposed on the first planarization layer 416a and the second connection electrode CE2. The second planarization layer 416b may be disposed to surround a part of the side surface of the light-emitting component LEDc. The second planarization layer 416b may be configured as a single layer or multilayer and made of benzocyclobutene or an acrylic-based organic material, for example. However, the present specification is not limited thereto.

The fourth connection electrode CE4 may be disposed on the second planarization layer 416b. Like the second connection electrode CE2, the fourth connection electrode CE4 is an electrode for electrically connecting the light-emitting component LEDc and the driving transistor DT. Specifically, the fourth connection electrode CE4 is an electrode for electrically connecting the second electrode NE2 of the second light-emitting element LED2 and the driving transistor DT. The fourth connection electrode CE4 may be disposed on the second planarization layer 416b and connected to the intermediate electrode CNT through contact holes formed in the first planarization layer 416a and the second planarization layer 416b. Therefore, the fourth connection electrode CE4 may be electrically connected to the driving transistor DT through the intermediate electrode CNT.

Meanwhile, the present specification is not limited to the configuration illustrated in the drawings. The fourth connection electrode CE4 may be disposed to overlap the second connection electrode CE2. That is, the fourth connection electrode CE4 may be electrically connected to the driving transistor DT through the second connection electrode CE2 and the intermediate electrode CNT. That is, the method of connecting the fourth connection electrode CE4 illustrated in FIG. 9 is provided for illustrative purposes only. The connection method and position of the fourth connection electrode CE4 for connecting the first light-emitting element LED1 and the second light-emitting element LED2 to the same driving transistor DT and operating the first light-emitting element LED1 and the second light-emitting element LED2 may be variously changed. However, the present specification is not limited thereto.

A third planarization layer 416c may be disposed on the second planarization layer 416b and the fourth connection electrode CE4. The third planarization layer 416c may be disposed to surround a part of the side surface of the light-emitting component LEDc. The third planarization layer 416c may be configured as a single layer or multilayer and made of benzocyclobutene or an acrylic-based organic material, for example. However, the present specification is not limited thereto.

The third connection electrode CE3 may be disposed on the third planarization layer 416c. The third connection electrode CE3 is an electrode for electrically connecting the second light-emitting element LED2 of the light-emitting component LEDc and the power line VDD. The third connection electrode CE3 may be disposed on the third planarization layer 416c and connected to the first connection electrode CE1 through contact holes formed in the first planarization layer 416a, the second planarization layer 416b, and the third planarization layer 416c. Therefore, the third connection electrode CE3 may be electrically connected to the power line VDD through the first connection electrode CE1. Specifically, the third connection electrode CE3 may electrically connect the first electrode PE2 of the second light-emitting element LED2 and the power line VDD.

In the display device 400 according to yet another embodiment of the present specification, the light-emitting component LEDc may include the first light-emitting element LED1 and the second light-emitting element LED2 coupled by the bonding layer BDLc. In this case, the first light-emitting element LED1 and the second light-emitting element LED2 may include magnetic elements so as to be autonomously assembled. Meanwhile, the first light-emitting element LED1 and the second light-emitting element LED2 may be shaped symmetrically with respect to the bonding layer BDLc. Therefore, the light-emitting component LEDc may be turned on even though the light-emitting component LEDc is assembled in any direction. That is, because the first light-emitting element LED1 and the second light-emitting element LED2 are symmetric, the electrodes disposed at outermost sides of the light-emitting component LEDc may be identical to each other. Therefore, the light-emitting component LEDc may be turned on even though the light-emitting component LEDc is assembled in any direction. That is, in the display device 400 according to yet another embodiment of the present specification, the first light-emitting element LED1 and the second light-emitting element LED2 are shaped symmetrically, such that the light-emitting component LEDc may be assembled in the two directions, which may improve a degree of freedom of assembling directionality of the light-emitting component LEDc.

In addition, in the display device 400 according to yet another embodiment of the present specification, the stacked structures of the first electrodes PE1 and PE2, the first semiconductor layers PL1 and PL2, the active layers EL1 and EL2, the second semiconductor layers NL1 and NL2, and the second electrodes NE1 and NE2 of the first and second light-emitting elements LED1 and LED2 may be opposite to each other. Therefore, the first electrodes PE1 and PE2 may be disposed at the outermost sides regardless of the assembling direction of the light-emitting component LEDc. In this case, the first electrodes PE1 and PE2 may each be made of a transparent material. Therefore, the light emission efficiency may be improved even though the light-emitting component LEDc is assembled in any direction.

In addition, in the display device 400 according to yet another embodiment of the present specification, the first light-emitting element LED1 and the second light-emitting element LED2, which emit light with the same color, may be coupled by the bonding layer BDLc. Therefore, the first light-emitting element LED1 and the second light-emitting element LED2 may be simultaneously turned on, thereby implementing high luminance.

In addition, in the display device 400 according to yet another embodiment of the present specification, the first light-emitting element LED1 and the second light-emitting element LED2 may be coupled by the bonding layer BDLc and simultaneously and autonomously assembled. Therefore, the light-emitting component LEDc may be relatively thick in comparison with a case in which only any one of the first light-emitting element LED1 and the second light-emitting element LED2 is autonomously assembled. Therefore, it is possible to minimize or reduce a problem in which the light-emitting component is broken because of a small thickness during the assembling process.

In particular, in the display device 400 according to yet another embodiment of the present specification, the bonding layer BDLc disposed between the first light-emitting element LED1 and the second light-emitting element LED2 may be made of an insulating material. That is, the bonding layer BDLc may space the first light-emitting element LED1 and the second light-emitting element LED2 apart while insulating the first light-emitting element LED1 and the second light-emitting element LED2. Therefore, the first light-emitting element LED1 and the second light-emitting element LED2 may operate independently. For example, the second electrodes NE1 and NE2 of the light-emitting component LEDc may be connected to the driving transistor DT through different connection electrodes. Specifically, the second electrode NE1 of the first light-emitting element LED1 may be connected to the driving transistor DT through the second connection electrode CE2, and the second electrode NE2 of the second light-emitting element LED2 may be connected to the driving transistor DT through the fourth connection electrode CE4. That is, the first light-emitting element LED1 and the second light-emitting element LED2 may simultaneously operate by means of different connection electrodes. Therefore, the second light-emitting element LED2 may be turned on even though the second connection electrode CE2, which connects the first light-emitting element LED1 and the driving transistor DT, is defective. On the contrary, the first light-emitting element LED1 may be turned on even though the fourth connection electrode CE4, which connects the second light-emitting element LED2 and the driving transistor DT, is defective. Therefore, it is possible to minimize or reduce a phenomenon in which the light-emitting component LEDc completely becomes a dark spot.

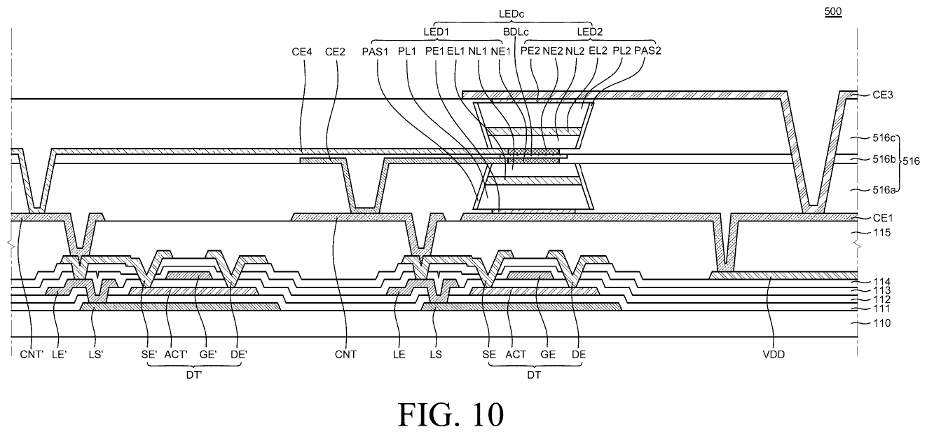

FIG. 10 is a cross-sectional view of a display device according to still yet another embodiment of the present specification. A display device 500 in FIG. 10 is substantially identical in configuration to the display device 400 in FIG. 9, except for intermediate electrodes CNT and CNT′, driving transistors DT and DT′, and the fourth connection electrode CE4. Therefore, repeated descriptions of the identical components will be omitted.

With reference to FIG. 10, the different intermediate electrodes CNT and CNT′ may be disposed on the overcoating layer 115. The intermediate electrodes CNT and CNT′ may electrically connect the different driving transistors DT and DT′ and the light-emitting component LEDc. The intermediate electrodes CNT and CNT′ may be connected to the source electrodes SE or the drain electrodes DE of the driving transistors DT and DT′ through contact holes formed in the overcoating layer 115. The intermediate electrodes CNT and CNT′ may each be electrically connected to the second electrode NE1 of the first light-emitting element LED1 and the second electrode NE2 of the second light-emitting element LED2 through the second connection electrode CE2 and the fourth connection electrode CE4. For example, the intermediate electrode CNT, which connects the second connection electrode CE2 and the first light-emitting element LED1, may be referred to as a first intermediate electrode, and the intermediate electrode CNT′, which connects the fourth connection electrode CE4 and the second light-emitting element LED2, may be referred to as a second intermediate electrode.

The second connection electrode CE2 may be disposed on a first planarization layer 516a. The second connection electrode CE2 is an electrode for electrically connecting the light-emitting component LEDc and the driving transistor DT. Specifically, the second connection electrode CE2 is an electrode for electrically connecting the second electrode NE1 of the first light-emitting element LED1 and the driving transistor DT. The second connection electrode CE2 may be disposed on the first planarization layer 516a and connected to the intermediate electrode CNT through a contact hole formed in the first planarization layer 516a. Meanwhile, the second connection electrode CE2 may be connected to the driving transistor DT different from the driving transistor DT′ to which the fourth connection electrode CE4 is connected. For example, the driving transistor DT connected to the second connection electrode CE2 may be referred to as a first driving transistor, and the driving transistor DT′ connected to the fourth connection electrode CE4 may be referred to as a second driving transistor. Therefore, the second connection electrode CE2 may be electrically connected to the first driving transistor DT through the first intermediate electrode CNT.

The fourth connection electrode CE4 may be disposed on a second planarization layer 516b. Like the second connection electrode CE2, the fourth connection electrode CE4 is an electrode for electrically connecting the light-emitting component LEDc and the driving transistor DT′. The fourth connection electrode CE4 may be disposed on the second planarization layer 516b and connected to the second intermediate electrode CNT′ through contact holes formed in the first planarization layer 516a and the second planarization layer 516b. Meanwhile, the fourth connection electrode CE4 may be connected to the driving transistor DT′ different from the driving transistor DT to which the second connection electrode CE2 is connected. For example, the driving transistor DT connected to the second connection electrode CE2 may be referred to as the first driving transistor, and the driving transistor DT′ connected to the fourth connection electrode CE4 may be referred to as the second driving transistor. Therefore, the fourth connection electrode CE4 may be electrically connected to the second driving transistor DT′ through the second intermediate electrode CNT′.

That is, the first and second light-emitting elements LED1 and LED2 may be respectively connected to the different driving transistors DT and DT′ through the second connection electrode CE2 and the fourth connection electrode CE4 and operate independently.

In the display device 500 according to still yet another embodiment of the present specification, the light-emitting component LEDc may include the first light-emitting element LED1 and the second light-emitting element LED2 coupled by the bonding layer BDLc. In this case, the first light-emitting element LED1 and the second light-emitting element LED2 may include magnetic elements so as to be autonomously assembled. Meanwhile, the first light-emitting element LED1 and the second light-emitting element LED2 may be shaped symmetrically with respect to the bonding layer BDLc. Therefore, the light-emitting component LEDc may be turned on even though the light-emitting component LEDc is assembled in any direction. That is, because the first light-emitting element LED1 and the second light-emitting element LED2 are symmetric, the electrodes disposed at outermost sides of the light-emitting component LEDc may be identical to each other. Therefore, the light-emitting component LEDc may be turned on even though the light-emitting component LEDc is assembled in any direction. That is, in the display device 500 according to still yet another embodiment of the present specification, the first light-emitting element LED1 and the second light-emitting element LED2 are shaped symmetrically, such that the light-emitting component LEDc may be assembled in the two directions, which may improve a degree of freedom of assembling directionality of the light-emitting component LEDc.

In addition, in the display device 500 according to still yet another embodiment of the present specification, the stacked structures of the first electrodes PE1 and PE2, the first semiconductor layers PL1 and PL2, the active layers EL1 and EL2, the second semiconductor layers NL1 and NL2, and the second electrodes NE1 and NE2 of the first and second light-emitting elements LED1 and LED2 may be opposite to each other. Therefore, the first electrodes PE1 and PE2 may be disposed at the outermost sides regardless of the assembling direction of the light-emitting component LEDc. In this case, the first electrodes PE1 and PE2 may each be made of a transparent material. Therefore, the light emission efficiency may be improved even though the light-emitting component LEDc is assembled in any direction.

In addition, in the display device 500 according to still yet another embodiment of the present specification, the first light-emitting element LED1 and the second light-emitting element LED2, which emit light with the same color, may be coupled by the bonding layer BDLc. Therefore, the first light-emitting element LED1 and the second light-emitting element LED2 may be simultaneously turned on, thereby implementing high luminance.

In addition, in the display device 500 according to still yet another embodiment of the present specification, the first light-emitting element LED1 and the second light-emitting element LED2 may be coupled by the bonding layer BDLc and simultaneously and autonomously assembled. Therefore, the light-emitting component LEDc may be relatively thick in comparison with a case in which only any one of the first light-emitting element LED1 and the second light-emitting element LED2 is autonomously assembled. Therefore, it is possible to minimize or reduce a problem in which the light-emitting component is broken because of a small thickness during the assembling process.

In particular, in the display device 500 according to still yet another embodiment of the present specification, the bonding layer BDLc disposed between the first light-emitting element LED1 and the second light-emitting element LED2 may be made of an insulating material. That is, the bonding layer BDLc may space the first light-emitting element LED1 and the second light-emitting element LED2 apart while insulating the first light-emitting element LED1 and the second light-emitting element LED2. Therefore, the first light-emitting element LED1 and the second light-emitting element LED2 may operate together or may, of course, operate independently. For example, the first and second light-emitting elements LED1 and LED2 may be respectively connected to the different driving transistors DT and DT′ through the second connection electrode CE2 and the fourth connection electrode CE4 and operate independently. Therefore, the second light-emitting element LED2 may be turned on even though the driving transistor DT connected to the first light-emitting element LED1 is defective. On the contrary, the first light-emitting element LED1 may be turned on even though the driving transistor DT′ connected to the second light-emitting element LED2 is defective. In addition, the second light-emitting element LED2 may be turned on even though the second connection electrode CE2, which connects the first light-emitting element LED1 and the driving transistor DT, is defective. On the contrary, the first light-emitting element LED1 may be turned on even though the fourth connection electrode CE4, which connects the second light-emitting element LED2 and the driving transistor DT′, is defective. Therefore, it is possible to minimize or reduce a phenomenon in which the light-emitting component LEDc completely becomes a dark spot.

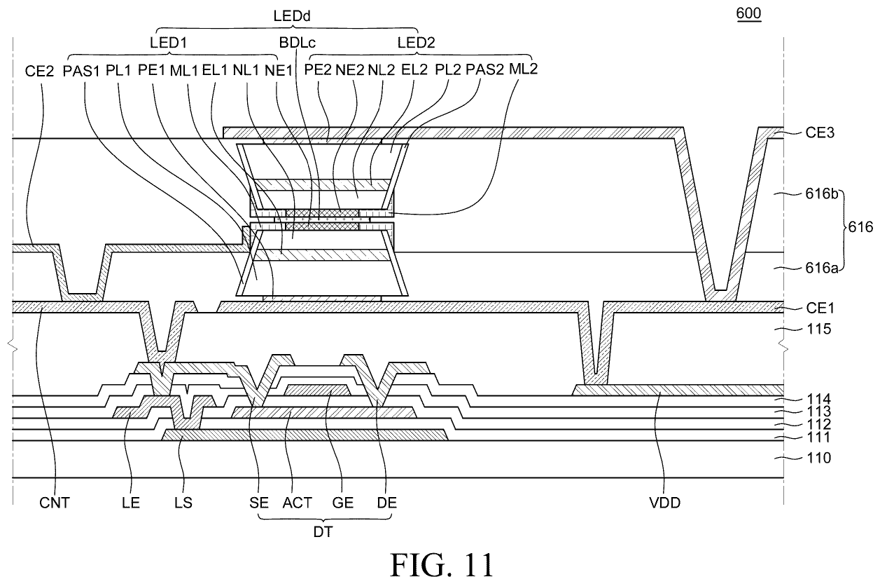

FIG. 11 is a cross-sectional view of a display device according to a further embodiment of the present specification. A display device 600 in FIG. 11 is substantially identical in configuration to the display device 300 in FIG. 8, except for the light-emitting component LEDd. Therefore, a repeated description will be omitted.

With reference to FIG. 11, the bonding layer BDLc may be made of an insulating material so that the first light-emitting element LED1 and the second light-emitting element LED2 operate independently. That is, the bonding layer BDLc may be disposed between the first light-emitting element LED1 and the second light-emitting element LED2 and insulate the first light-emitting element LED1 and the second light-emitting element LED2. Therefore, the second electrode NE1 of the first light-emitting element LED1 and the second electrode NE2 of the second light-emitting element LED2 may be disposed to be spaced apart from each other by the bonding layer BDLc. Therefore, as described below, in the display device, the first light-emitting element LED1 and the second light-emitting element LED2 may be connected to the same driving transistor and operate together. Of course, the first light-emitting element LED1 and the second light-emitting element LED2 may be connected to different connection electrodes or driving transistors and operated and turned on independently.

The first and second light-emitting elements LED1 and LED2 may respectively include the auxiliary electrodes ML1 and ML2 that surround the second electrodes NE1 and NE2. The auxiliary electrodes ML1 and ML2 may be disposed to extend to a side surface of the light-emitting component LEDd, thereby facilitating the electrical connection in the display device to be described below. In this case, the auxiliary electrodes ML1 and ML2 may be disposed to extend to the side surfaces of the first and second light-emitting elements LED1 and LED2 to facilitate the electrical connection regardless of the assembling direction of the light-emitting component LEDd. That is, the auxiliary electrodes ML1 and ML2 may be disposed to protrude from the side surfaces of the first and second light-emitting elements LED1 and LED2. Therefore, the auxiliary electrodes ML1 and ML2 may cover partial areas of the passivation films PAS1 and PAS2 that surround the side surface of the light-emitting component LEDd.

Meanwhile, FIG. 11 illustrates that the auxiliary electrodes ML1 and ML2 extend from the side surface of the light-emitting component LEDd. However, the present specification is not limited thereto. The second electrodes NE1 and NE2 may be disposed to extend from the side surface of the light-emitting component LEDd. That is, the second electrodes NE1 and NE2 may be disposed to protrude from the side surfaces of the first and second light-emitting elements LED1 and LED2. Therefore, the second electrodes NE1 and NE2 may cover partial areas of the passivation films PAS1 and PAS2 that surround the side surface of the light-emitting component LEDd. However, the present specification is not limited to the configuration illustrated in the drawings.

A first planarization layer 616a may be disposed on the overcoating layer 115, the intermediate electrode CNT, and the first connection electrode CE1 to surround a part of the side surface of the light-emitting component LEDd. The first planarization layer 616a may be disposed in a range in which the first planarization layer 616a does not overlap the auxiliary electrodes ML1 and ML2 so that the first planarization layer 616a connects the auxiliary electrodes ML1 and ML2 and the second connection electrode CE2. Therefore, a height of the first planarization layer 616a may be relatively low in comparison with a case in which the auxiliary electrodes ML1 and ML2 are not disposed to extend. However, the present specification is not limited thereto.

The second connection electrode CE2 may be disposed on the first planarization layer 616a. The second connection electrode CE2 is an electrode for electrically connecting the light-emitting component LEDd and the driving transistor DT. The second connection electrode CE2 may be disposed on the first planarization layer 616a and connected to the intermediate electrode CNT through a contact hole formed in the first planarization layer 616a. Therefore, the second connection electrode CE2 may be electrically connected to the driving transistor DT through the intermediate electrode CNT.

Specifically, the second connection electrode CE2 may be in direct contact with the auxiliary electrode ML1 of the first light-emitting element LED1. Therefore, the second connection electrode CE2 may electrically connect the second electrode NE1 of the first light-emitting element LED1 and the driving transistor DT through the auxiliary electrode ML1.

Meanwhile, the second connection electrode CE2 may also be connected to the auxiliary electrode ML2 of the second light-emitting element LED2. That is, the second connection electrode CE2 may electrically connect the second electrode NE1 of the first light-emitting element LED1, the second electrode NE2 of the second light-emitting element LED2, and the driving transistor DT. Therefore, the first light-emitting element LED1 and the second light-emitting element LED2 may operate together by means of the second connection electrode CE2.

In this case, because the auxiliary electrodes ML1 and ML2 are disposed to extend to the side surface of the light-emitting component LEDd, the second connection electrode CE2 may be easily in contact with the auxiliary electrodes ML1 and ML2 on the side surface of the light-emitting component LEDd and thus easily electrically connected to the second electrodes NE1 and NE2.

Meanwhile, as described above, the second electrodes NE1 and NE2 may be disposed to extend to the side surface of the light-emitting component LEDd. In this case, the second connection electrode CE2 may be in direct contact with the second electrodes NE1 and NE2 and electrically connect the first light-emitting element LED1, the second light-emitting element LED2, and the driving transistor DT. The present specification is not limited to the configuration illustrated in the drawings.

In the display device 600 according to the further embodiment of the present specification, the light-emitting component LEDd may include the first light-emitting element LED1 and the second light-emitting element LED2 coupled by the bonding layer BDLc. In this case, the first light-emitting element LED1 and the second light-emitting element LED2 may include magnetic elements so as to be autonomously assembled. Meanwhile, the first light-emitting element LED1 and the second light-emitting element LED2 may be shaped symmetrically with respect to the bonding layer BDLc. Therefore, the light-emitting component LEDd may be turned on even though the light-emitting component LEDd is assembled in any direction. That is, because the first light-emitting element LED1 and the second light-emitting element LED2 are symmetric, the electrodes disposed at outermost sides of the light-emitting component LEDd may be identical to each other. Therefore, the light-emitting component LEDd may be turned on even though the light-emitting component LEDd is assembled in any direction. That is, in the display device 600 according to the further embodiment of the present specification, the first light-emitting element LED1 and the second light-emitting element LED2 are shaped symmetrically, such that the light-emitting component LEDd may be assembled in the two directions, which may improve a degree of freedom of assembling directionality of the light-emitting component LEDd.

In addition, in the display device 600 according to the further embodiment of the present specification, the stacked structures of the first electrodes PE1 and PE2, the first semiconductor layers PL1 and PL2, the active layers EL1 and EL2, the second semiconductor layers NL1 and NL2, and the second electrodes NE1 and NE2 of the first and second light-emitting elements LED1 and LED2 may be opposite to each other. Therefore, the first electrodes PE1 and PE2 may be disposed at the outermost sides regardless of the assembling direction of the light-emitting component LEDd. In this case, the first electrodes PE1 and PE2 may each be made of a transparent material. Therefore, the light emission efficiency may be improved even though the light-emitting component LEDd is assembled in any direction.

In addition, in the display device 600 according to the further embodiment of the present specification, the first light-emitting element LED1 and the second light-emitting element LED2, which emit light with the same color, may be coupled by the bonding layer BDLc. Therefore, the first light-emitting element LED1 and the second light-emitting element LED2 may be simultaneously turned on, thereby implementing high luminance.

In addition, in the display device 600 according to the further embodiment of the present specification, the first light-emitting element LED1 and the second light-emitting element LED2 may be coupled by the bonding layer BDLc and simultaneously and autonomously assembled. Therefore, the light-emitting component LEDd may be relatively thick in comparison with a case in which only any one of the first light-emitting element LED1 and the second light-emitting element LED2 is autonomously assembled. Therefore, it is possible to minimize or reduce a problem in which the light-emitting component is broken because of a small thickness during the assembling process.

In particular, in the display device 600 according to the further embodiment of the present specification, the bonding layer BDLc disposed between the first light-emitting element LED1 and the second light-emitting element LED2 may be made of an insulating material. That is, the bonding layer BDLc may space the first light-emitting element LED1 and the second light-emitting element LED2 apart while insulating the first light-emitting element LED1 and the second light-emitting element LED2. Therefore, the first light-emitting element LED1 and the second light-emitting element LED2 may operate together or may, of course, operate independently. For example, the second connection electrode CE2 may be connected to both the second electrode NE1 of the first light-emitting element LED1 and the second electrode NE2 of the second light-emitting element LED2. Specifically, the second connection electrode CE2 may be in direct contact with the auxiliary electrodes ML1 and ML2 of the light-emitting component LEDd and connect the second electrodes NE1 and NE2 of the light-emitting component LEDd to the driving transistor DT. Therefore, the first light-emitting element LED1 and the second light-emitting element LED2 may operate simultaneously. In this case, the auxiliary electrodes ML1 and ML2 of the light-emitting component LEDd may be disposed to extend to the side surface of the light-emitting component LEDd, thereby facilitating the electrical connection with the second connection electrode CE2. In this case, the auxiliary electrodes ML1 and ML2 may be disposed to protrude from the side surfaces of the first and second light-emitting elements LED1 and LED2. Therefore, the coupling properties with the second connection electrode CE2 may be improved regardless of the assembling direction of the light-emitting component LEDd.

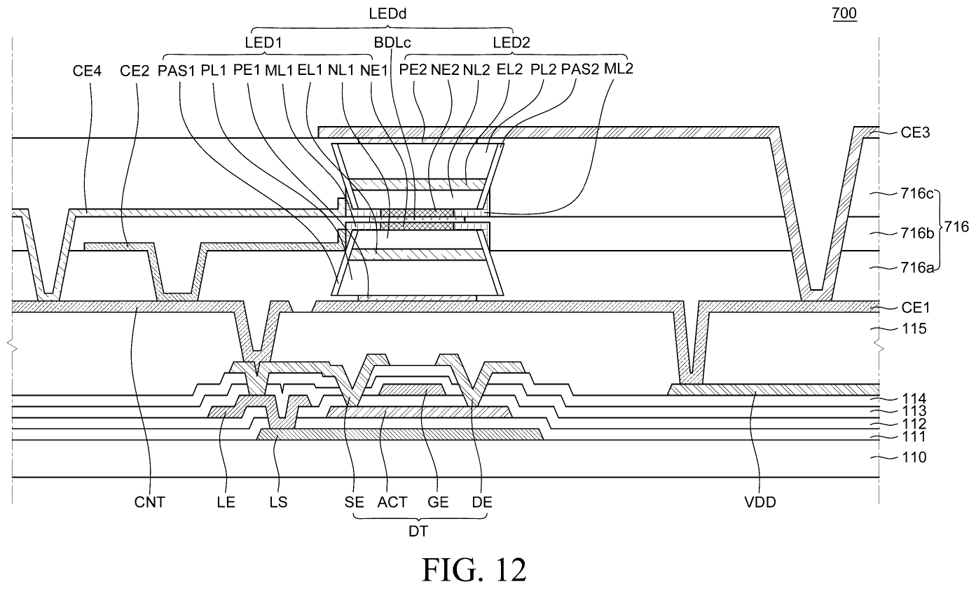

FIG. 12 is a cross-sectional view of a display device according to another further embodiment of the present specification. A display device 700 in FIG. 12 is substantially identical in configuration to the display device 600 in FIG. 11, except for the fourth connection electrode CE4 and a planarization layer 716. Therefore, repeated descriptions of the identical components will be omitted.

The second connection electrode CE2 may be disposed on a first planarization layer 716a. The second connection electrode CE2 is an electrode for electrically connecting the light-emitting component LEDd and the driving transistor DT. Specifically, the second connection electrode CE2 is an electrode for electrically connecting the second electrode NE1 of the first light-emitting element LED1 and the driving transistor DT. The second connection electrode CE2 may be disposed on the first planarization layer 716a and connected to the intermediate electrode CNT through a contact hole formed in the first planarization layer 716a. Therefore, the second connection electrode CE2 may be electrically connected to the driving transistor DT through the intermediate electrode CNT.

Specifically, the second connection electrode CE2 may be in direct contact with the auxiliary electrode ML1 of the first light-emitting element LED1. Therefore, the second connection electrode CE2 may electrically connect the second electrode NE1 of the first light-emitting element LED1 and the driving transistor DT through the auxiliary electrode ML1.

In this case, because the auxiliary electrode ML1 is disposed to extend to the side surface of the light-emitting component LEDd, the second connection electrode CE2 may be easily in contact with the auxiliary electrode ML1 and thus easily electrically connected to the second electrode NE1 of the first light-emitting element LED1.

A second planarization layer 716b may be disposed on the first planarization layer 716a and the second connection electrode CE2. The second planarization layer 716b may be disposed to surround a part of the side surface of the light-emitting component LEDd. The second planarization layer 716b may be configured as a single layer or multilayer and made of benzocyclobutene or an acrylic-based organic material, for example. However, the present specification is not limited thereto.

The fourth connection electrode CE4 may be disposed on the second planarization layer 716b. Like the second connection electrode CE2, the fourth connection electrode CE4 is an electrode for electrically connecting the light-emitting component LEDd and the driving transistor DT. Specifically, the fourth connection electrode CE4 is an electrode for electrically connecting the second electrode NE2 of the second light-emitting element LED2 and the driving transistor DT. The fourth connection electrode CE4 may be disposed on the second planarization layer 716b and connected to the intermediate electrode CNT through contact holes formed in the first planarization layer 716a and the second planarization layer 716b. Therefore, the fourth connection electrode CE4 may be electrically connected to the driving transistor DT through the intermediate electrode CNT.

Specifically, the second connection electrode CE2 may be in direct contact with the auxiliary electrode ML2 of the second light-emitting element LED2. Therefore, the second connection electrode CE2 may electrically connect the second electrode NE2 of the second light-emitting element LED2 and the driving transistor DT through the auxiliary electrode ML2.

In this case, because the auxiliary electrode ML2 is disposed to extend to the side surface of the light-emitting component LEDd, the second connection electrode CE2 may be easily in contact with the auxiliary electrode ML2 and thus easily electrically connected to the second electrode NE2 of the first light-emitting element LED2.

Meanwhile, the present specification is not limited to the configuration illustrated in the drawings. The fourth connection electrode CE4 may be disposed to overlap the second connection electrode CE2. That is, the fourth connection electrode CE4 may be electrically connected to the driving transistor DT through the second connection electrode CE2 and the intermediate electrode CNT. That is, the method of connecting the fourth connection electrode CE4 illustrated in FIG. 12 is provided for illustrative purposes only. The connection method and position of the fourth connection electrode CE4 for connecting the first light-emitting element LED1 and the second light-emitting element LED2 to the same driving transistor DT and operating the first light-emitting element LED1 and the second light-emitting element LED2 may be variously changed. However, the present specification is not limited thereto.

A third planarization layer 716c may be disposed on the second planarization layer 716b and the fourth connection electrode CE4. The third planarization layer 716c may be disposed to surround a part of the side surface of the light-emitting component LEDd. The third planarization layer 716c may be configured as a single layer or multilayer and made of benzocyclobutene or an acrylic-based organic material, for example. However, the present specification is not limited thereto.

The third connection electrode CE3 may be disposed on the third planarization layer 716c. The third connection electrode CE3 is an electrode for electrically connecting the second light-emitting element LED2 of the light-emitting component LEDd and the power line VDD. The third connection electrode CE3 may be disposed on the third planarization layer 716c and connected to the first connection electrode CE1 through contact holes formed in the first planarization layer 716a, the second planarization layer 716b, and the third planarization layer 716c. Therefore, the third connection electrode CE3 may be electrically connected to the power line VDD through the first connection electrode CE1. Specifically, the third connection electrode CE3 may electrically connect the first electrode PE2 of the second light-emitting element LED2 and the power line VDD.

In the display device 700 according to another further embodiment of the present specification, the light-emitting component LEDd may include the first light-emitting element LED1 and the second light-emitting element LED2 coupled by the bonding layer BDLc. In this case, the first light-emitting element LED1 and the second light-emitting element LED2 may include magnetic elements so as to be autonomously assembled. Meanwhile, the first light-emitting element LED1 and the second light-emitting element LED2 may be shaped symmetrically with respect to the bonding layer BDLc. Therefore, the light-emitting component LEDd may be turned on even though the light-emitting component LEDd is assembled in any direction. That is, in this case, because the first light-emitting element LED1 and the second light-emitting element LED2 are symmetric, the electrodes disposed at outermost sides of the light-emitting component LEDd may be identical to each other. Therefore, the light-emitting component LEDd may be turned on even though the light-emitting component LEDd is assembled in any direction. That is, in the display device 700 according to another further embodiment of the present specification, the first light-emitting element LED1 and the second light-emitting element LED2 are shaped symmetrically, such that the light-emitting component LEDd may be assembled in the two directions, which may improve a degree of freedom of assembling directionality of the light-emitting component LEDd.

In addition, in the display device 700 according to another further embodiment of the present specification, the stacked structures of the first electrodes PE1 and PE2, the first semiconductor layers PL1 and PL2, the active layers EL1 and EL2, the second semiconductor layers NL1 and NL2, and the second electrodes NE1 and NE2 of the first and second light-emitting elements LED1 and LED2 may be opposite to each other. Therefore, the first electrodes PE1 and PE2 may be disposed at the outermost sides regardless of the assembling direction of the light-emitting component LEDd. In this case, the first electrodes PE1 and PE2 may each be made of a transparent material. Therefore, the light emission efficiency may be improved even though the light-emitting component LEDd is assembled in any direction.

In addition, in the display device 700 according to another further embodiment of the present specification, the first light-emitting element LED1 and the second light-emitting element LED2, which emit light with the same color, may be coupled by the bonding layer BDLc. Therefore, the first light-emitting element LED1 and the second light-emitting element LED2 may be simultaneously turned on, thereby implementing high luminance.

In addition, in the display device 700 according to another further embodiment of the present specification, the first light-emitting element LED1 and the second light-emitting element LED2 may be coupled by the bonding layer BDLc and simultaneously and autonomously assembled. Therefore, the light-emitting component LEDd may be relatively thick in comparison with a case in which only any one of the first light-emitting element LED1 and the second light-emitting element LED2 is autonomously assembled. Therefore, it is possible to minimize or reduce a problem in which the light-emitting component is broken because of a small thickness during the assembling process.

In particular, in the display device 700 according to another further embodiment of the present specification, the bonding layer BDLc disposed between the first light-emitting element LED1 and the second light-emitting element LED2 may be made of an insulating material. That is, the bonding layer BDLc may space the first light-emitting element LED1 and the second light-emitting element LED2 apart while insulating the first light-emitting element LED1 and the second light-emitting element LED2. Therefore, the first light-emitting element LED1 and the second light-emitting element LED2 may operate together or may, of course, operate independently. For example, the second electrodes NE1 and NE2 of the light-emitting component LEDd may be connected to the same driving transistor DT through different connection electrodes. Specifically, the second electrode NE1 of the first light-emitting element LED1 may be connected to the same driving transistor DT through the second connection electrode CE2, and the second electrode NE2 of the second light-emitting element LED2 may be connected to the same driving transistor DT through the fourth connection electrode CE4. That is, the first light-emitting element LED1 and the second light-emitting element LED2 may simultaneously operate by means of different connection electrodes. Therefore, the second light-emitting element LED2 may be turned on even though the second connection electrode CE2, which connects the first light-emitting element LED1 and the driving transistor DT, is defective. On the contrary, the first light-emitting element LED1 may be turned on even though the fourth connection electrode CE4, which connects the second light-emitting element LED2 and the driving transistor DT, is defective. Therefore, it is possible to minimize or reduce a phenomenon in which the light-emitting component LEDd completely becomes a dark spot.

In particular, in the display device 700 according to another further embodiment of the present specification, the second connection electrode CE2 and the fourth connection electrode CE4 may be respectively in direct contact with the auxiliary electrode ML1 of the first light-emitting element LED1 and the auxiliary electrode ML2 of the second light-emitting element LED2 and connect the second electrodes NE1 and NE2 of the light-emitting component LEDd to the driving transistor DT. In this case, the auxiliary electrodes ML1 and ML2 of the light-emitting component LEDd may be disposed to extend to the side surface of the light-emitting component LEDd, thereby facilitating the electrical connection with the second connection electrode CE2 and the fourth connection electrode CE4. In this case, the auxiliary electrodes ML1 and ML2 may be disposed to protrude from the side surfaces of the first and second light-emitting elements LED1 and LED2. Therefore, the coupling properties with the second connection electrode CE2 and the fourth connection electrode CE4 may be improved regardless of the assembling direction of the light-emitting component LEDd.

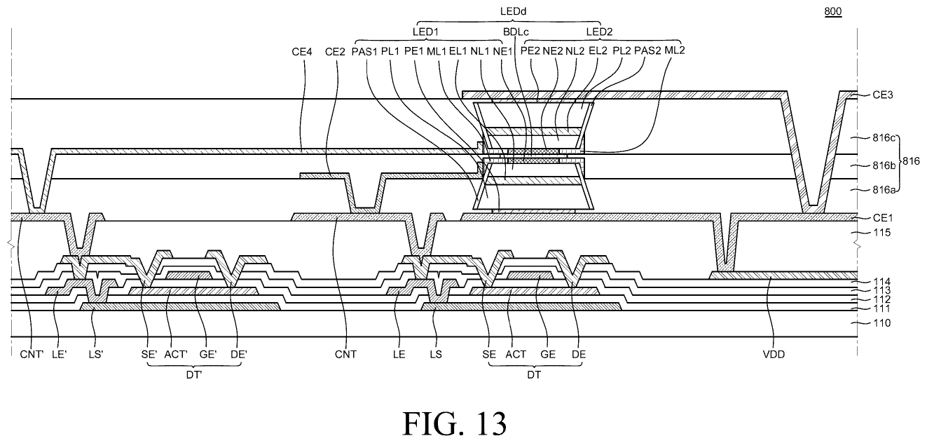

FIG. 13 is a cross-sectional view of a display device according to still another further embodiment of the present specification. A display device 800 in FIG. 13 is substantially identical in configuration to the display device 700 in FIG. 12, except for intermediate electrodes CNT and CNT′, driving transistors DT and DT′, and the fourth connection electrode CE4. Therefore, repeated descriptions of the identical components will be omitted.

With reference to FIG. 13, the different intermediate electrodes CNT and CNT′ may be disposed on the overcoating layer 115. The intermediate electrodes CNT and CNT′ may electrically connect the different driving transistors DT and DT′ and the light-emitting component LEDd. The intermediate electrodes CNT and CNT′ may be connected to the source electrodes SE or the drain electrodes DE of the driving transistors DT and DT′ through contact holes formed in the overcoating layer 115. The intermediate electrodes CNT and CNT′ may each be electrically connected to the second electrode NE1 of the first light-emitting element LED1 and the second electrode NE2 of the second light-emitting element LED2 through the second connection electrode CE2 and the fourth connection electrode CE4. For example, the intermediate electrode CNT, which connects the second connection electrode CE2 and the first light-emitting element LED1, may be referred to as a first intermediate electrode, and the intermediate electrode CNT′, which connects the fourth connection electrode CE4 and the second light-emitting element LED2, may be referred to as a second intermediate electrode.

The second connection electrode CE2 may be disposed on a first planarization layer 816a. The second connection electrode CE2 is an electrode for electrically connecting the light-emitting component LEDd and the driving transistor DT. Specifically, the second connection electrode CE2 is an electrode for electrically connecting the second electrode NE1 of the first light-emitting element LED1 and the driving transistor DT. The second connection electrode CE2 may be disposed on the first planarization layer 816a and connected to the intermediate electrode CNT through a contact hole formed in the first planarization layer 816a. Meanwhile, the second connection electrode CE2 may be connected to the driving transistor DT different from the driving transistor DT′ to which the fourth connection electrode CE4 is connected. For example, the driving transistor DT connected to the second connection electrode CE2 may be referred to as the first driving transistor, and the driving transistor DT′ connected to the fourth connection electrode CE4 may be referred to as the second driving transistor. Therefore, the second connection electrode CE2 may be electrically connected to the first driving transistor DT through the first intermediate electrode CNT.

Specifically, the second connection electrode CE2 may be in direct contact with the auxiliary electrode ML1 of the first light-emitting element LED1. Therefore, the second connection electrode CE2 may electrically connect the second electrode NE1 of the first light-emitting element LED1 and the first driving transistor DT through the auxiliary electrode ML1.

The fourth connection electrode CE4 may be disposed on a second planarization layer 816b. Like the second connection electrode CE2, the fourth connection electrode CE4 is an electrode for electrically connecting the light-emitting component LEDd and the second driving transistor DT′. The fourth connection electrode CE4 may be disposed on the second planarization layer 816b and connected to the second intermediate electrode CNT′ through contact holes formed in the first planarization layer 816a and the second planarization layer 816b. Therefore, the fourth connection electrode CE4 may be electrically connected to the second driving transistor DT′ through the second intermediate electrode CNT′.

Specifically, the fourth connection electrode CE4 may be in direct contact with the auxiliary electrode ML2 of the second light-emitting element LED2. Therefore, the fourth connection electrode CE4 may electrically connect the second electrode NE2 of the second light-emitting element LED2 and the second driving transistor DT′ through the auxiliary electrode ML2.

That is, the first and second light-emitting elements LED1 and LED2 may be respectively connected to the different transistors DT and DT′ through the second connection electrode CE2 and the fourth connection electrode CE4 and operate independently.

Meanwhile, the drawings illustrate that the auxiliary electrodes ML1 and ML2 are disposed to extend to the side surface of the light-emitting component LEDd. However, the second electrodes NE1 and NE2 may be disposed to extend to the side surface of the light-emitting component LEDd. In this case, the second connection electrode CE2 and the fourth connection electrode CE4 may be respectively in direct contact with the second electrode NE1 of the first light-emitting element LED1 and the second electrode NE2 of the second light-emitting element LED2. The present specification is not limited to the configuration illustrated in the drawings.

In the display device 800 according to still another further embodiment of the present specification, the light-emitting component LEDd may include the first light-emitting element LED1 and the second light-emitting element LED2 coupled by the bonding layer BDLc. In this case, the first light-emitting element LED1 and the second light-emitting element LED2 may include magnetic elements so as to be autonomously assembled. Meanwhile, the first light-emitting element LED1 and the second light-emitting element LED2 may be shaped symmetrically with respect to the bonding layer BDLc. Therefore, the light-emitting component LEDd may be turned on even though the light-emitting component LEDd is assembled in any direction. That is, because the first light-emitting element LED1 and the second light-emitting element LED2 are symmetric, the electrodes disposed at outermost sides of the light-emitting component LEDd may be identical to each other. Therefore, the light-emitting component LEDd may be turned on even though the light-emitting component LEDd is assembled in any direction. That is, in the display device 800 according to still another further embodiment of the present specification, the first light-emitting element LED1 and the second light-emitting element LED2 are shaped symmetrically, such that the light-emitting component LEDd may be assembled in the two directions, which may improve a degree of freedom of assembling directionality of the light-emitting component LEDd.

In addition, in the display device 800 according to still another further embodiment of the present specification, the stacked structures of the first electrodes PE1 and PE2, the first semiconductor layers PL1 and PL2, the active layers EL1 and EL2, the second semiconductor layers NL1 and NL2, and the second electrodes NE1 and NE2 of the first and second light-emitting elements LED1 and LED2 may be opposite to each other. Therefore, the first electrodes PE1 and PE2 may be disposed at the outermost sides regardless of the assembling direction of the light-emitting component LEDd. In this case, the first electrodes PE1 and PE2 may each be made of a transparent material. Therefore, the light emission efficiency may be improved even though the light-emitting component LEDd is assembled in any direction.

In addition, in the display device 800 according to still another further embodiment of the present specification, the first light-emitting element LED1 and the second light-emitting element LED2, which emit light with the same color, may be coupled by the bonding layer BDLc. Therefore, the first light-emitting element LED1 and the second light-emitting element LED2 may be simultaneously turned on, thereby implementing high luminance.

In addition, in the display device 800 according to still another further embodiment of the present specification, the first light-emitting element LED1 and the second light-emitting element LED2 may be coupled by the bonding layer BDLc and simultaneously and autonomously assembled. Therefore, the light-emitting component LEDd may be relatively thick in comparison with a case in which only any one of the first light-emitting element LED1 and the second light-emitting element LED2 is autonomously assembled. Therefore, it is possible to minimize or reduce a problem in which the light-emitting component is broken because of a small thickness during the assembling process.

In particular, in the display device 800 according to still another further embodiment of the present specification, the bonding layer BDLc disposed between the first light-emitting element LED1 and the second light-emitting element LED2 may be made of an insulating material. That is, the bonding layer BDLc may space the first light-emitting element LED1 and the second light-emitting element LED2 apart while insulating the first light-emitting element LED1 and the second light-emitting element LED2. Therefore, the first light-emitting element LED1 and the second light-emitting element LED2 may operate together or may, of course, operate independently. For example, the first and second light-emitting elements LED1 and LED2 may be respectively connected to the different driving transistors DT and DT′ through the second connection electrode CE2 and the fourth connection electrode CE4 and operate independently. Therefore, the second light-emitting element LED2 may be turned on even though the driving transistor DT connected to the first light-emitting element LED1 is defective. On the contrary, the first light-emitting element LED1 may be turned on even though the driving transistor DT′ connected to the second light-emitting element LED2 is defective. In addition, the second light-emitting element LED2 may be turned on even though the second connection electrode CE2, which connects the first light-emitting element LED1 and the driving transistor DT, is defective. On the contrary, the first light-emitting element LED1 may be turned on even though the fourth connection electrode CE4, which connects the second light-emitting element LED2 and the driving transistor DT′, is defective. Therefore, it is possible to minimize or reduce a phenomenon in which the light-emitting component LEDd completely becomes a dark spot.

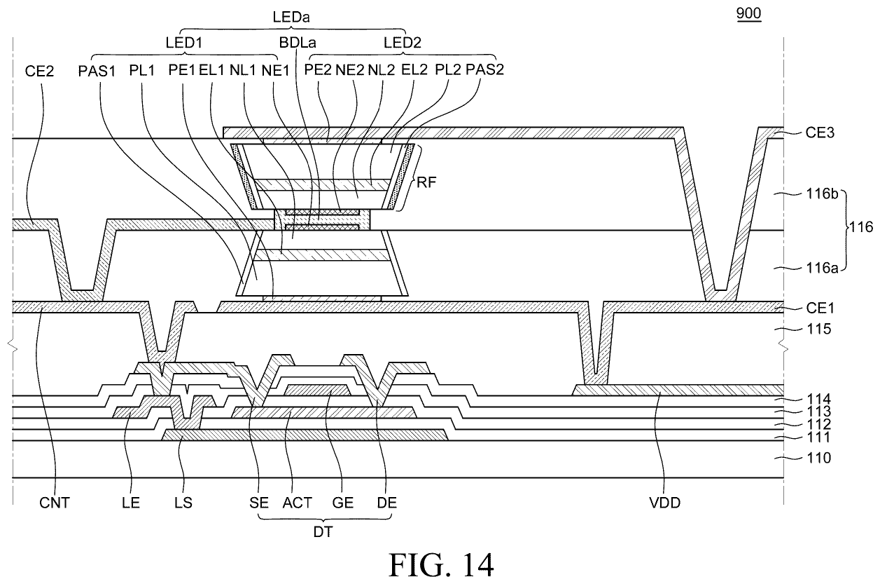

FIG. 14 is a cross-sectional view of a display device according to yet another further embodiment of the present specification. A display device 900 in FIG. 14 is substantially identical in configuration to the display device 100 in FIG. 6, except for a reflective layer RF. Therefore, a repeated description will be omitted.

With reference to FIG. 14, the reflective layer RF may be disposed on the side surface of the second light-emitting element LED2. Specifically, the reflective layer RF may be disposed on the side surface of the passivation film PAS2 of the second light-emitting element LED2 and emit the light, which is emitted from the first light-emitting element LED1, toward the front side, thereby improving the luminance.

Meanwhile, after the first light-emitting element LED1 and the second light-emitting element LED2 are disposed on the substrate 110, the reflective layer RF may be disposed only on the second light-emitting element LED2 disposed at the upper side. For example, in case that the first light-emitting element LED1 and the second light-emitting element LED2 are assembled in the opposite directions and the first light-emitting element LED1 is disposed above the second light-emitting element LED2, the reflective layer RF may be disposed on the side surface of the first light-emitting element LED1. The present specification is not limited to the configuration illustrated in the drawings.

That is, because the reflective layer RF is disposed after the first light-emitting element LED1 and the second light-emitting element LED2 are assembled and transferred, the reflective layer RF may be disposed on the side surface of the light-emitting component LEDa regardless of the assembling direction, thereby improving the luminance.

Meanwhile, although not illustrated in the drawings, in each of the display devices according to various embodiments of the present specification, the reflective layer RF may be disposed on the side surface of the second light-emitting element LED2.

In the display device 900 according to yet another further embodiment of the present specification, the light-emitting component LEDa may include the first light-emitting element LED1 and the second light-emitting element LED2 coupled by the bonding layer BDLa. In this case, the first light-emitting element LED1 and the second light-emitting element LED2 may include magnetic elements so as to be autonomously assembled. Meanwhile, the first light-emitting element LED1 and the second light-emitting element LED2 may be shaped symmetrically with respect to the bonding layer BDLa. Therefore, the light-emitting component LEDa may be turned on even though the light-emitting component LEDa is assembled in any direction. That is, because the first light-emitting element LED1 and the second light-emitting element LED2 are symmetric, the electrodes disposed at outermost sides of the light-emitting component LEDa may be identical to each other. Therefore, the light-emitting component LEDa may be turned on even though the light-emitting component LEDa is assembled in any direction. That is, in the display device 900 according to yet another further embodiment of the present specification, the first light-emitting element LED1 and the second light-emitting element LED2 are shaped symmetrically, such that the light-emitting component LEDa may be assembled in the two directions, which may improve a degree of freedom of assembling directionality of the light-emitting component LEDa.

In addition, in the display device 900 according to yet another further embodiment of the present specification, the stacked structures of the first electrodes PE1 and PE2, the first semiconductor layers PL1 and PL2, the active layers EL1 and EL2, the second semiconductor layers NL1 and NL2, and the second electrodes NE1 and NE2 of the first and second light-emitting elements LED1 and LED2 may be opposite to each other. Therefore, the first electrodes PE1 and PE2 may be disposed at the outermost sides regardless of the assembling direction of the light-emitting component LEDa. In this case, the first electrodes PE1 and PE2 may each be made of a transparent material. Therefore, the light emission efficiency may be improved even though the light-emitting component LEDa is assembled in any direction.

In addition, in the display device 900 according to yet another further embodiment of the present specification, the first light-emitting element LED1 and the second light-emitting element LED2, which emit light with the same color, may be electrically connected through the bonding layer BDLa. Therefore, the first light-emitting element LED1 and the second light-emitting element LED2 may be simultaneously turned on, thereby implementing high luminance.

In addition, in the display device 900 according to yet another further embodiment of the present specification, the first light-emitting element LED1 and the second light-emitting element LED2 may be coupled by the bonding layer BDLa and simultaneously and autonomously assembled. Therefore, the light-emitting component LEDa may be relatively thick in comparison with a case in which only any one of the first light-emitting element LED1 and the second light-emitting element LED2 is autonomously assembled. Therefore, it is possible to minimize or reduce a problem in which the light-emitting component is broken because of a small thickness during the assembling process.

In particular, in the display device 900 according to yet another further embodiment of the present specification, the reflective layer RF may be disposed on the side surface of the second light-emitting element LED2. The reflective layer RF may emit the light, which is emitted from the first light-emitting element LED1 disposed below the second light-emitting element LED2, toward the front side, thereby improving the luminance. In this case, the reflective layer RF may be disposed after the first light-emitting element LED1 and the second light-emitting element LED2 are assembled and transferred. Therefore, the reflective layer RF may be disposed on the side surface of the light-emitting component LEDa regardless of the assembling direction, thereby improving the luminance.

The exemplary embodiments of the present disclosure can also be described as follows:

According to an aspect of the present disclosure, there is provided a light-emitting component. The light-emitting component includes a first light-emitting element, a first light-emitting element a second light-emitting element disposed on the first light-emitting element and a bonding layer disposed between the first light-emitting element and the second light-emitting element. The first light-emitting element and the second light-emitting element each have a structure in which a first electrode, a first semiconductor layer, an active layer, a second semiconductor layer, and a second electrode are sequentially stacked. The order in which the first electrode, the first semiconductor layer, the active layer, the second semiconductor layer, and the second electrode of the first light-emitting element are stacked and the order in which the first electrode, the first semiconductor layer, the active layer, the second semiconductor layer, and the second electrode of the second light-emitting element are stacked are opposite to each other.

The first light-emitting element and the second light-emitting element may be shaped symmetrically with respect to the bonding layer.

The first light-emitting element and the second light-emitting element emit may light with the same color.

The bonding layer may be made of a metallic material, and the second electrode of the first light-emitting element and the second electrode of the second light-emitting element may be electrically connected by the bonding layer.

A width of the bonding layer may be smaller than a width of the first semiconductor layer of the first light-emitting element and a width of the first semiconductor layer of the second light-emitting element.

The bonding layer may be made of an insulating material and the second electrode of the first light-emitting element and the second electrode of the second light-emitting element may be spaced apart from each other by the bonding layer.

The first light-emitting element and the second light-emitting element each may further comprise a passivation film configured to surround a side surface of the first semiconductor layer, a side surface of the active layer, and a side surface of the second semiconductor layer. The second electrode of the first light-emitting element and the second electrode of the second light-emitting element may be disposed to extend to cover a partial area of the passivation film.

The first light-emitting element and the second light-emitting element each may further comprise a passivation film configured to surround a side surface of the first semiconductor layer, a side surface of the active layer, and a side surface of the second semiconductor layer and an auxiliary electrode configured to surround the second electrode. The auxiliary electrode of the first light-emitting element and the auxiliary electrode of the second light-emitting element may be disposed to extend to cover a partial area of the passivation film.

The first light-emitting element and the second light-emitting element each may further comprise a passivation film configured to surround a side surface of the first semiconductor layer, a side surface of the active layer, and a side surface of the second semiconductor layer. The bonding layer may be disposed to extend to cover a partial area of the passivation film.

The first electrode of the first light-emitting element and the first electrode of the second light-emitting element may be disposed at outermost sides of the light-emitting component. The first electrode of the first light-emitting element and the first electrode of the second light-emitting element may be transparent electrodes.

The second electrode of the first light-emitting element and the second electrode of the second light-emitting element may include magnetic elements.

According to an aspect of the present disclosure, there is provided a display device. The display device includes a substrate comprising a plurality of subpixels, a plurality of transistors disposed on the substrate, a power line disposed on the substrate and a plurality of light-emitting components disposed on the plurality of transistors in the plurality of subpixels. The plurality of light-emitting components each includes a first light-emitting element, a second light-emitting element disposed on the first light-emitting element and a bonding layer disposed between the first light-emitting element and the second light-emitting element. The first light-emitting element and the second light-emitting element each have a structure in which a first electrode, a first semiconductor layer, an active layer, a second semiconductor layer, and a second electrode are sequentially stacked. The order in which the first electrode, the first semiconductor layer, the active layer, the second semiconductor layer, and the second electrode of the first light-emitting element are stacked and the order in which the first electrode, the first semiconductor layer, the active layer, the second semiconductor layer, and the second electrode of the second light-emitting element are stacked are opposite to each other.

The display device may further include a first connection electrode configured to electrically connect the first electrode of the first light-emitting element and the power line, a second connection electrode configured to electrically connect the second electrode of the first light-emitting element and one of the plurality of transistors and a third connection electrode configured to electrically connect the first electrode of the second light-emitting element and the power line.

The bonding layer may be made of a metallic material and the second electrode of the second light-emitting element may be electrically connected to the second connection electrode.

The first light-emitting element and the second light-emitting element each may further include a passivation film configured to surround a side surface of the first semiconductor layer, a side surface of the active layer, and a side surface of the second semiconductor layer. The bonding layer may be disposed to extend to cover a partial area of the passivation film and the bonding layer may be in direct contact with the second connection electrode.

The display device may further include a plurality of planarization layers disposed to surround side surfaces of the plurality of light-emitting components. The first connection electrode may be disposed below the plurality of planarization layers and the second connection electrode and the third connection electrode may be respectively disposed on different layers among the plurality of planarization layers.

The bonding layer may be made of an insulating material and the first electrode of the first light-emitting element and the first electrode of the second light-emitting element may be spaced apart from each other by the bonding layer.

The display device may further include a fourth connection electrode configured to electrically connect the second electrode of the second light-emitting element and another of the plurality of transistors.

The first light-emitting element and the second light-emitting element each may further include a passivation film configured to surround a side surface of the first semiconductor layer, a side surface of the active layer, and a side surface of the second semiconductor layer. The second electrode of the first light-emitting element and the second electrode of the second light-emitting element may be disposed to extend to cover a partial area of the passivation film. The second electrode of the first light-emitting element may be in direct contact with the second connection electrode. The second electrode of the second light-emitting element may be in direct contact with the fourth connection electrode.

The first light-emitting element and the second light-emitting element each may further include a passivation film configured to surround a side surface of the first semiconductor layer, a side surface of the active layer, and a side surface of the second semiconductor layer and an auxiliary electrode configured to surround the second electrode. The auxiliary electrode of the first light-emitting element and the auxiliary electrode of the second light-emitting element may be disposed to extend to cover a partial area of the passivation film. The auxiliary electrode of the first light-emitting element may be in direct contact with the second connection electrode. The auxiliary electrode of the second light-emitting element may be in direct contact with the fourth connection electrode.

The display device may further include a plurality of planarization layers disposed to surround side surfaces of the plurality of light-emitting components. The first connection electrode may be disposed below the plurality of planarization layers and the second connection electrode, the third connection electrode, and the fourth connection electrode may be respectively disposed on different layers among the plurality of planarization layers.

The display device further comprises: a fourth connection electrode configured to electrically connect the second electrode of the second light-emitting element and the one of the plurality of transistors.

The display device may further include a reflective layer disposed on a side surface of the second light-emitting element.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A light-emitting component comprising:
a first light-emitting element;
a second light-emitting element on the first light-emitting element; and
a bonding layer between the first light-emitting element and the second light-emitting element,
wherein the first light-emitting element and the second light-emitting element each have a structure in which a first electrode, a first semiconductor layer, an active layer, a second semiconductor layer, and a second electrode are sequentially stacked, and
wherein the order in which the first electrode, the first semiconductor layer, the active layer, the second semiconductor layer, and the second electrode of the first light-emitting element are stacked and the order in which the first electrode, the first semiconductor layer, the active layer, the second semiconductor layer, and the second electrode of the second light-emitting element are stacked are opposite to each other.

2. The light-emitting component of claim 1, wherein the first light-emitting element and the second light-emitting element are shaped symmetrically with respect to the bonding layer.

3. The light-emitting component of claim 1, wherein the first light-emitting element and the second light-emitting element emit light with the same color.

4. The light-emitting component of claim 1, wherein the bonding layer is made of a metallic material, and the second electrode of the first light-emitting element and the second electrode of the second light-emitting element are electrically connected by the bonding layer.

5. The light-emitting component of claim 4, wherein a width of the bonding layer is smaller than a width of the first semiconductor layer of the first light-emitting element and a width of the first semiconductor layer of the second light-emitting element.

6. The light-emitting component of claim 4, wherein the first light-emitting element and the second light-emitting element each further comprise a passivation film configured to surround a side surface of the first semiconductor layer, a side surface of the active layer, and a side surface of the second semiconductor layer, and
wherein the bonding layer is disposed to extend to cover a partial area of the passivation film.

7. The light-emitting component of claim 1, wherein the bonding layer is made of an insulating material, and
wherein the second electrode of the first light-emitting element and the second electrode of the second light-emitting element are spaced apart from each other by the bonding layer.

8. The light-emitting component of claim 7, wherein the first light-emitting element and the second light-emitting element each further comprise a passivation film configured to surround a side surface of the first semiconductor layer, a side surface of the active layer, and a side surface of the second semiconductor layer, and
wherein the second electrode of the first light-emitting element and the second electrode of the second light-emitting element are disposed to extend to cover a partial area of the passivation film.

9. The light-emitting component of claim 7, wherein the first light-emitting element and the second light-emitting element each further comprise:
a passivation film configured to surround a side surface of the first semiconductor layer, a side surface of the active layer, and a side surface of the second semiconductor layer; and
an auxiliary electrode configured to surround the second electrode,
wherein the auxiliary electrode of the first light-emitting element and the auxiliary electrode of the second light-emitting element are disposed to extend to cover a partial area of the passivation film.

10. The light-emitting component of claim 1, wherein the first electrode of the first light-emitting element and the first electrode of the second light-emitting element are disposed at outermost sides of the light-emitting component, and
wherein the first electrode of the first light-emitting element and the first electrode of the second light-emitting element are transparent electrodes.

11. The light-emitting component of claim 1, wherein the second electrode of the first light-emitting element and the second electrode of the second light-emitting element include magnetic elements.

12. A display device comprising:
a plurality of subpixels on a substrate;
a plurality of transistors on the substrate;
a power line on the substrate; and
a plurality of light-emitting components on the plurality of transistors in the plurality of subpixels,
wherein the plurality of light-emitting components each comprises:
a first light-emitting element;
a second light-emitting element on the first light-emitting element; and
a bonding layer between the first light-emitting element and the second light-emitting element,
wherein the first light-emitting element and the second light-emitting element each have a structure in which a first electrode, a first semiconductor layer, an active layer, a second semiconductor layer, and a second electrode are sequentially stacked, and
wherein the order in which the first electrode, the first semiconductor layer, the active layer, the second semiconductor layer, and the second electrode of the first light-emitting element are stacked and the order in which the first electrode, the first semiconductor layer, the active layer, the second semiconductor layer, and the second electrode of the second light-emitting element are stacked are opposite to each other.

13. The display device of claim 12, further comprising:
a first connection electrode configured to electrically connect the first electrode of the first light-emitting element and the power line;
a second connection electrode configured to electrically connect the second electrode of the first light-emitting element and one of the plurality of transistors; and
a third connection electrode configured to electrically connect the first electrode of the second light-emitting element and the power line.

14. The display device of claim 13, wherein the bonding layer is made of a metallic material, and
wherein the second electrode of the second light-emitting element is electrically connected to the second connection electrode.

15. The display device of claim 14, wherein the first light-emitting element and the second light-emitting element each further comprise a passivation film configured to surround a side surface of the first semiconductor layer, a side surface of the active layer, and a side surface of the second semiconductor layer,
wherein the bonding layer is disposed to extend to cover a partial area of the passivation film, and
wherein the bonding layer is in direct contact with the second connection electrode.

16. The display device of claim 13, further comprising:
a plurality of planarization layers disposed to surround side surfaces of the plurality of light-emitting components,
wherein the first connection electrode is disposed below the plurality of planarization layers, and
wherein the second connection electrode and the third connection electrode are respectively on different layers among the plurality of planarization layers.

17. The display device of claim 13, wherein the bonding layer is made of an insulating material, and
wherein the first electrode of the first light-emitting element and the first electrode of the second light-emitting element are spaced apart from each other by the bonding layer.

18. The display device of claim 17, further comprising:
a fourth connection electrode configured to electrically connect the second electrode of the second light-emitting element and another transistor of the plurality of transistors.

19. The display device of claim 18, wherein the first light-emitting element and the second light-emitting element each further comprise a passivation film configured to surround a side surface of the first semiconductor layer, a side surface of the active layer, and a side surface of the second semiconductor layer,
wherein the second electrode of the first light-emitting element and the second electrode of the second light-emitting element are disposed to extend to cover a partial area of the passivation film,
wherein the second electrode of the first light-emitting element is in direct contact with the second connection electrode, and
wherein the second electrode of the second light-emitting element is in direct contact with the fourth connection electrode.

20. The display device of claim 18, wherein the first light-emitting element and the second light-emitting element each further comprise:
a passivation film configured to surround a side surface of the first semiconductor layer, a side surface of the active layer, and a side surface of the second semiconductor layer; and
an auxiliary electrode configured to surround the second electrode,
wherein the auxiliary electrode of the first light-emitting element and the auxiliary electrode of the second light-emitting element are disposed to extend to cover a partial area of the passivation film,
wherein the auxiliary electrode of the first light-emitting element is in direct contact with the second connection electrode, and
wherein the auxiliary electrode of the second light-emitting element is in direct contact with the fourth connection electrode.

21. The display device of claim 18, further comprising:
a plurality of planarization layers disposed to surround side surfaces of the plurality of light-emitting components,
wherein the first connection electrode is disposed below the plurality of planarization layers, and
wherein the second connection electrode, the third connection electrode, and the fourth connection electrode are respectively on different layers among the plurality of planarization layers.

22. The display device of claim 17, further comprising:
a fourth connection electrode configured to electrically connect the second electrode of the second light-emitting element and the one transistor of the plurality of transistors.

23. The display device of claim 12, further comprising:
a reflective layer on a side surface of the second light-emitting element.
